(19) United States
(12) Patent Application Publication
(10) Pub. No.: US 2026/0214970 A1
(43) Pub. Date: Jul. 23, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Katsumi NAKAMURA, Tokyo (JP)

(73) Assignee: Mitsubishi Electric Corporation, Tokyo (JP)

(21) Appl. No.: 19/412,297

(22) Filed: Dec. 8, 2025

(30) Foreign Application Priority Data
Jan. 21, 2025 (JP) 2025-008336

(51) Int. Cl. H10D 84/00; H10D 62/17; H10D 62/53; H10D 84/01; H10P 32/10

(52) U.S. Cl. CPC H10D 84/161; H10D 62/393; H10D 62/53; H10D 84/0109; H10P 32/18

(57) ABSTRACT

A semiconductor substrate includes a drift layer, and a first semiconductor layer and a second semiconductor layer provided between the drift layer and a second electrode. The second semiconductor layer is provided on the second electrode side of the first semiconductor layer, one of the first semiconductor layer and the second semiconductor layer contains point defects, while another of the first semiconductor layer and the second semiconductor layer does not contain point defects, and a maximum oxygen concentration of the semiconductor substrate, maximum [Oᵢ], and an impurity concentration of a first conductivity type in the drift layer, C_{drift}, have a predetermined relationship.

### BACKGROUND

### Technical Field

The present disclosure relates to a semiconductor device and a method of manufacturing the semiconductor device.

### Description of the Background Art

For example, Japanese Patent Application Laid-Open No. 2023-179647 proposes a technique for controlling a doping concentration in a drift layer of an n-type semiconductor wafer, with respect to a power semiconductor device, which is a semiconductor device.

According to the technique disclosed in Japanese Patent Application Laid-Open No. 2023-179647, in a floating zone (FZ) wafer and a magnetic field applied Czochralski (MCZ) wafer, hydrogen is introduced into Si from a lower surface side (for example, a cathode layer side or a collector layer side) in a region where a diode and an insulated gate bipolar transistor (IGBT) are to be formed. The introduced hydrogen interacts with thermal donors caused by the oxygen concentration in the wafer, thereby forming a hydrogen-induced donor layer as an n-type buffer layer. Furthermore, through diffusion of hydrogen in the depth direction, the concentration of the n-type drift layer is increased relative to an original doping concentration, and a profile of the doping concentration is provided with a gradient.

However, in an FZ wafer, for example, where the concentration of oxygen as an impurity in Si is low, oxygen diffuses into the Si wafer during the heat treatment following thermal oxide film formation in the wafer process so as to compensate for the oxygen supply in Si. As a result, a profile in which the oxygen concentration decreases in the depth direction is formed. Since the hydrogen-induced donor layer is susceptible to the influence of oxygen in Si, when thermal donors are utilized in an FZ wafer having a profile in which the oxygen concentration decreases in the depth direction, the impurity profile of the hydrogen-induced donor layer undergoes unstable variation in the depth direction. Consequently, there arises a problem in that the breakdown voltage characteristics become unstable.

Further, for example, when carrier lifetime control is performed on an MCZ wafer using charged particles (for example, electron beams, protons, helium), impurities (for example, oxygen and carbon) in the MCZ wafer react with defects induced by the charged particles. As a result, there arises a problem that the influence of impurities in the MCZ wafer on the performance of the power semiconductor device becomes pronounced, and instability of the hydrogen-induced donor layer is triggered.

### SUMMARY

The present disclosure has been made in view of the above-described problems, and an object thereof is to provide a technique capable of improving performance of a semiconductor device.

A semiconductor device according to the present disclosure includes: a semiconductor substrate that has a first main surface and a second main surface opposite to the first main surface; and a first electrode and a second electrode that are respectively provided on the first main surface and the second main surface, wherein the semiconductor substrate includes: a drift layer of a first conductivity type which is provided between the first main surface and the second main surface, and a first semiconductor layer and a second semiconductor layer that are provided between the drift layer and the second electrode, each having a peak impurity concentration of the first conductivity type, the second semiconductor layer is provided on a side of the first semiconductor layer toward the second electrode, one of the first semiconductor layer and the second semiconductor layer contains point defects while another of the first semiconductor layer and the second semiconductor layer does not contain the point defects, and when a maximum oxygen concentration in the semiconductor substrate calculated using a conversion coefficient of ASTM F121-79 (Old ASTM) is defined as maximum [Oᵢ] and an impurity concentration of the first conductivity type in the drift layer is defined as C_{drift}, a relationship of maximum [Oᵢ]=9.40×10¹⁶×ln(C_{drift})−2.27×10¹⁸ is satisfied.

It is possible to improve the performance of the semiconductor device.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a power semiconductor device according to a first preferred embodiment;

FIGS. 2A and 2B are cross-sectional views illustrating a configuration of a diode;

FIG. 3 is a graph illustrating a relationship between an oxygen concentration of a semiconductor substrate and an impurity concentration of an n⁻-type drift layer;

FIG. 4 is a graph illustrating PL spectra of the diode analyzed by a PL method;

FIG. 5 is a graph illustrating a relationship between an on-voltage as well as a current density of a cross point and a dose amount of an n⁺² layer;

FIG. 6 is a graph illustrating a cross point of the diode;

FIG. 7 is a graph illustrating a trade-off characteristic between a switching loss and the on-voltage;

FIGS. 8A to 8C are cross-sectional views illustrating a configuration of a diode;

FIG. 9 is a graph illustrating an impurity profile in a depth direction at a B-B′ plane and a C-C′ plane in FIG. 8B;

FIGS. 10A and 10B are graphs illustrating PL spectra of the diode analyzed by the PL method;

FIG. 11 is a graph illustrating a trade-off characteristic between a switching loss and an on-voltage for the diode illustrated in FIGS. 8A and 8B;

FIG. 12 is a graph illustrating an output characteristic of the diode at 298 K for the diode illustrated in FIG. 8B;

FIG. 13 is a graph illustrating output characteristics of the diode at 298 K and 423 K for the diode illustrated in FIGS. 8A and 8B;

FIG. 14 is a graph illustrating an operation temperature dependency of the on-voltage for the diode illustrated in FIGS. 8A and 8B;

FIG. 15 is a graph illustrating a leakage characteristic when a reverse bias is applied to a main junction for the diode illustrated in FIGS. 8A and 8B;

FIG. 16 is a graph illustrating a waveform during a recovery operation in a small-current mode of the diode for the diode illustrated in FIGS. 8A and 8B;

FIG. 17 is a graph illustrating a relationship between V_{snap-off}, which is a maximum V_{AK}, and a power supply voltage, during the recovery operation;

FIG. 18 is a graph illustrating a time-dependent change of the on-voltage during a continuous energization test of the diode for the diode illustrated in FIGS. 8A and 8B;

FIG. 19 is a graph illustrating a relationship between V_{snap-off}, which is the maximum V_{AK}, and the power supply voltage, during the recovery operation for the diode illustrated in FIGS. 8A and 8B;

FIG. 20 is a schematic diagram illustrating a configuration of a diode according to a third preferred embodiment and an impurity profile thereof;

FIG. 21 is a graph illustrating PL spectra for n-type buffer layers 8 and 9 constituting the diode analyzed by the PL method;

FIG. 22 is a graph illustrating a relationship between a ratio of a PL intensity of trap C and a depth of an n-type buffer layer;

FIG. 23 is a graph illustrating a snappy recovery waveform of a 1200 V class diode at a low temperature;

FIG. 24 is a graph illustrating a relationship between a safe operating temperature range and the ratio of the PL intensity of trap C in a snappy recovery operation mode of the 1200 V class diode;

FIG. 25 is a graph illustrating a relationship between a reverse recovery charge amount and the power supply voltage of the 1200 V class diode during the recovery operation;

FIG. 26 is a graph illustrating a relationship between the reverse recovery charge amount and an operating temperature of the 1200 V class diode during the recovery operation;

FIG. 27 is a graph illustrating a relationship between a blockable temperature and the power supply voltage in the snappy recovery operation mode of the 1200 V class diode;

FIGS. 28A and 28B are cross-sectional views illustrating configurations of IGBTs;

FIG. 29 is a graph illustrating turn-off waveforms of the 1200 V class IGBTs having the structures illustrated in FIGS. 28A and 28B;

FIG. 30 is a graph illustrating a relationship between a maximum blockable energy density at the time of a short circuit and a final device thickness of the 1200 V class IGBTs having the structures illustrated in FIGS. 28A and 28B;

FIG. 31 is a graph illustrating a trade-off characteristic between a switching loss and an on-voltage of the 1200 V class IGBTs having the structures illustrated in FIGS. 28A and 28B;

FIGS. 32 to 34 are cross-sectional views each illustrating a configuration of a semiconductor device according to a fifth preferred embodiment;

FIGS. 35A to 37C are cross-sectional views each illustrating steps of a method of manufacturing an IGBT according to a sixth preferred embodiment;

FIG. 38 is a flowchart illustrating the steps of the method of manufacturing the IGBT according to the sixth preferred embodiment;

FIGS. 39A to 41C are cross-sectional views each illustrating steps of a method of manufacturing a diode according to a seventh preferred embodiment;

FIGS. 42 and 43 are flowcharts each illustrating the steps of the method of manufacturing the diode according to the seventh preferred embodiment;

FIG. 44 is a graph illustrating a relationship between the ratio of the PL intensity of trap C and an annealing temperature in an annealing step of the n-type buffer layer 8; and

FIG. 45 is a graph illustrating a relationship between PL intensities of traps B and C at points A and B in FIG. 22 and an annealing time in the annealing step of the n-type buffer layer 8.

### DESCRIPTION OF THE PREFERRED EMBODIMENTS

Hereinafter, preferred embodiments will be described with reference to the accompanying drawings. The features described in the following preferred embodiments are examples, and all the features are not necessarily indispensable. In the following description, the same components are denoted by the same or similar reference signs in a plurality of preferred embodiments, and different components will be mainly described. In addition, in the following description, specific positions and directions such as “upper”, “lower”, “left”, “right”, “front”, and “back” do not necessarily match positions and directions in actual implementation. The fact that a certain portion has a higher density than another portion may indicate that, for example, the average density or peak density of the certain portion is higher than the average density or peak density of the other portion. Conversely, the fact that a certain portion has a lower density than another portion may indicate that, for example, the average density or peak density of the certain portion is lower than the average density or peak density of the other portion. In the following description, the first conductivity type is an n-type and the second conductivity type is a p-type, but the first conductivity type may be the p-type and the second conductivity type may be the n-type.

### First Preferred Embodiment

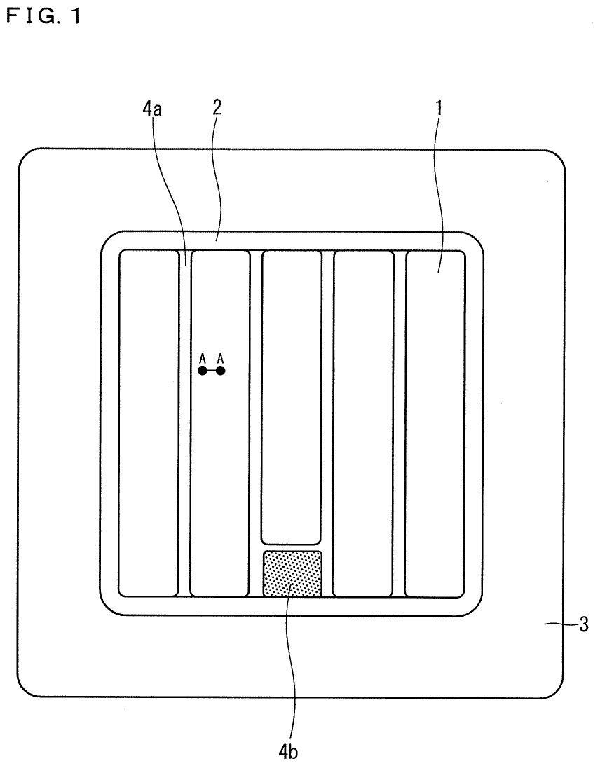

FIG. 1 is a plan view illustrating a configuration of a power semiconductor device which is one example of a semiconductor device according to a first preferred embodiment. In the semiconductor device of FIG. 1, an active region 1, an interface region 2, and a termination region 3 are defined.

The active region 1 is a region that guarantees basic performance of the semiconductor device, and, for example, an insulated gate bipolar transistor (IGBT), a metal oxide semiconductor field effect transistor (MOSFET), a diode, or a reverse conducting IGBT (RC-IGBT) including an IGBT and a diode is provided as a semiconductor element. The interface region 2 is a region between the active region 1 and the termination region 3, and is a region that supports destruction tolerance during dynamic operation of the semiconductor device or supports inherent performance of the semiconductor element provided in the active region 1. The termination region 3 is a region surrounding the active region 1 and the interface region 2, and is a region that guarantees stability and reliability of withstand voltage holding and withstand voltage characteristics in a static state, suppresses destruction tolerance defects during dynamic operation, or supports basic performance of the semiconductor device.

In FIG. 1, a case is illustrated in which an IGBT is provided in the active region 1, and a surface gate wiring portion 4a and a gate pad portion 4b are provided in the active region 1, but the present invention is not limited thereto. For example, when a diode is provided in the active region 1, the surface gate wiring portion 4a and the gate pad portion 4b may not be provided in the active region 1. In the first preferred embodiment, a case will mainly be described in which a diode having a p-i-n structure is provided in the active region 1. The diode having the p-i-n structure may be a power diode or may be a freewheeling diode (FWD).

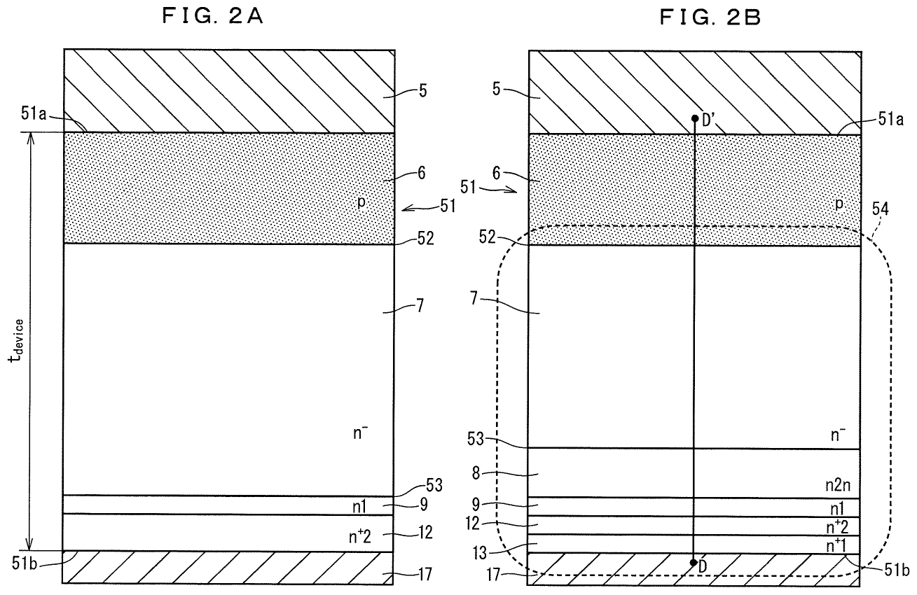

FIG. 2A is a cross-sectional view illustrating a configuration of a conventional diode (hereinafter, also referred to as “con. p-i-n diode”). FIG. 2B is a cross-sectional view illustrating a configuration of a diode according to the first preferred embodiment (hereinafter, also referred to as “new p-i-n diode”). These cross-sectional views correspond to a cross section taken along A-A′ of FIG. 1.

First, among the components of the diode according to the first preferred embodiment, components that are substantially the same as those of the conventional diode will mainly be described.

The diode includes a semiconductor substrate 51, a first electrode 5, and a second electrode 17. The semiconductor substrate 51 has a front surface 51a, which is a first main surface, and a back surface 51b, which is a second main surface opposite to the first main surface. The first electrode 5 is provided on the front surface 51a and is included, for example, in aluminum wiring. The second electrode 17 is provided on the back surface 51b and is included, for example, in a metal film. A final device thickness (t_{device}) corresponding to the thickness of the semiconductor substrate 51 is, for example, 40 μm to 700 μm.

The semiconductor substrate 51 according to the first preferred embodiment is a semiconductor wafer of silicon (Si) manufactured by a magnetic field applied czochralski (MCZ) method (hereinafter, also referred to as “MCZ wafer”). Oxygen and carbon introduced as impurities during the manufacture of the MCZ wafer are present at interstitial positions and substitutional lattice positions, respectively, in a Si single crystal. Accordingly, in the following description, the oxygen concentration and carbon concentration of the semiconductor substrate 51 are denoted as [Oᵢ] and [Cₛ], respectively, with the respective first letter of “interstitial” and “substitutional” appended. In general, the [Oᵢ] of an MCZ wafer is two to three orders of magnitude higher than the [Oᵢ] of a floating zone (FZ) wafer, whereas the [Cₛ] of the MCZ wafer and the [Cₛ] of the FZ wafer are comparable.

The semiconductor substrate 51 includes a p-type anode layer 6, an n⁻-type drift layer 7 which is a drift layer, an n-type buffer layer 9, and an n⁺-type cathode layer 12 which is a first semiconductor layer. It should be noted that, in the present description, an impurity concentration refers to the concentration of an element different from Si, and the element concerned will be described as appropriate. Furthermore, an element forming a diffusion layer is referred to as dopant.

The n⁻-type drift layer 7 corresponds to a portion of the MCZ wafer, which is the semiconductor substrate 51, where no impurities (ions or dopants) have substantially been newly implanted. An n-type impurity of the n⁻-type drift layer 7 is, for example, phosphorus (P) or antimony (Sb), and an impurity concentration C_{drift} of the n⁻-type drift layer 7 is, for example, 1.0×10¹² atoms/cm³ to 5.0×10¹⁴ atoms/cm³.

In the production of large-diameter semiconductor wafers, due to the segregation phenomenon of dopants in a Si single crystal ingot, the impurity concentration in the crystal axis direction of the Si single crystal ingot (that is, the impurity concentration C_{drift} of the n⁻-type drift layer 7) tends to have large variation. However, the evaporation rate of antimony (1.3×10⁻¹ cm/sec) is about three orders of magnitude higher than the evaporation rate of phosphorus (1.6×10⁻⁴ cm/sec). Therefore, by using antimony as the n-type impurity of the semiconductor wafer, that is, the semiconductor substrate 51, and manufacturing the Si single crystal with an evaporation control technology that takes advantage of the characteristic of antimony, the variation in the impurity concentration C_{drift} in the crystal axis direction of the Si single crystal ingot can be suppressed.

The n⁻-type drift layer 7 is provided between the front surface 51a and the back surface 51b, and, in the case of a diode, is provided from a main junction 52 on the front surface 51a side to a junction 53 on the back surface 51b side. During voltage holding of the semiconductor element, a reverse bias is applied to the main junction 52. When a reverse bias is applied to the main junction 52, a depletion layer extends from the main junction 52 toward the back surface 51b, and the electric field strength becomes maximum at the main junction 52. The junction 53 is a portion that the depletion layer, extending from the main junction 52 toward the back surface 51b during voltage holding, contacts, and is the portion where the electric field strength becomes the second highest after the main junction 52 during voltage holding.

The p-type anode layer 6 is provided between the first electrode 5 and the n⁻-type drift layer 7. The p-type anode layer 6 has, for example, boron (B) as a p-type impurity, with a surface impurity concentration of, for example, 1.0×10¹⁶ atoms/cm³ or more, and a peak impurity concentration of, for example, 2.0×10¹⁶ atoms/cm³ to 1.0×10¹⁸ atoms/cm³. The depth of the p-type anode layer 6 from the front surface 51a is, for example, 2.0 μm to 10.0 μm.

The n-type buffer layer 9 is provided between the n⁻-type drift layer 7 and the second electrode 17. The n-type buffer layer 9 has, for example, arsenic (As) or phosphorus (P) as an n-type impurity, with a maximum peak impurity concentration (C_{P,n1}) of, for example, 1.0×10¹⁵ atoms/cm³ to 5.0×10¹⁶ atoms/cm³, and a depth (X_{j,pn1}) from the back surface 51b of, for example, 1.0 μm to 5.0 μm. In the drawings and the like, the n-type buffer layer 9 may also be abbreviated as “n1”.

The n⁺-type cathode layer 12 is provided between the n-type buffer layer 9 and the second electrode 17. The n⁺-type cathode layer 12 has, for example, arsenic (As) or phosphorus (P) as an n-type impurity, with a peak impurity concentration of, for example, 1.0×10¹⁷ atoms/cm³ to 1.0×10¹⁹ atoms/cm³, and a depth from the back surface 51b of, for example, 0.3 μm to 0.5 μm. In the drawings and the like, the n⁺-type cathode layer 12 may also be abbreviated as “n⁺2”.

Next, among the components of the diode according to the first preferred embodiment, components that are different from those of the conventional diode will mainly be described. The semiconductor substrate 51 according to the first preferred embodiment further includes an n-type buffer layer 8 and an n⁺-type cathode layer 13 which is a second semiconductor layer. That is, in the first preferred embodiment, the first semiconductor layer and the second semiconductor layer are the n⁺-type cathode layer 12 and the n⁺-type cathode layer 13, respectively.

The n-type buffer layer 8 is provided between the n⁻-type drift layer 7 and the second electrode 17, and is provided on the n⁻-type drift layer 7 side of the n-type buffer layer 9. The n-type impurity concentration of the n-type buffer layer 8 is smaller than the n-type impurity concentration of the n-type buffer layer 9 and greater than the n-type impurity concentration of the n⁻-type drift layer 7.

The n-type buffer layer 8 has, for example, proton (H⁺) as an n-type impurity, with a maximum peak impurity concentration (C_{p,n2n}) of, for example, less than C_{P,n1} of the n-type buffer layer 9, and preferably 0.01×C_{P,n1} or less, and a depth (X_{j,pn2}) from the back surface 51b of, for example, 20 μm to 30 μm deeper than the depth (X_{j,pn1}) of the n-type buffer layer 9. In the drawings and the like, the n-type buffer layer 8 may also be abbreviated as “n2n”.

The two buffer layers (the n-type buffer layers 8 and 9) are provided for stabilization of the voltage holding capability in an OFF state, reduction of power consumption in an OFF state, improvement of controllability during dynamic operation, and enhancement of breakdown tolerance. For example, the n-type buffer layer 8 is provided for reduction of power consumption in an OFF state, improvement of controllability during dynamic operation, and enhancement of breakdown tolerance, and the n-type buffer layer 9 is provided for stabilization of the voltage holding capability in an OFF state. The carrier lifetime of the n⁻-type drift layer 7, the n-type buffer layer 8, and the n-type buffer layer 9 may satisfy the relational expression described in a sixth preferred embodiment.

The n⁺-type cathode layer 13 is provided between the n⁻-type drift layer 7 and the second electrode 17, and on the second electrode 17 side of the n⁺-type cathode layer 12. The n⁺-type cathode layer 13 has, for example, arsenic (As) or phosphorus (P) as an n-type impurity, with a peak impurity concentration of, for example, 1.0×10¹⁸ atoms/cm³ to 1.0×10²⁰ atoms/cm³, and a depth from the back surface 51b of, for example, 0.1 μm to 0.2 μm. In the drawings and the like, the n⁺-type cathode layer 13 may also be abbreviated as “n⁺1”.

As will be described later, among the n⁺-type cathode layers 12 and 13, the n⁺-type cathode layer 13, which is the second semiconductor layer, contains point defects, whereas the n⁺-type cathode layer 12, which is the first semiconductor layer, contains no point defects.

The n⁻-type drift layer 7, the n-type buffer layers 8 and 9, and the n⁺-type cathode layers 12 and 13 form a vertical structure 54. The vertical structure 54 is a region that ensures stability and reliability of performance of total loss (the sum of an on-voltage loss, a turn-on state loss, and a turn-off state loss), withstand voltage holding and withstand voltage characteristics in a static state, and leakage characteristics (off-state loss) during voltage holding at a high temperature. The vertical structure 54 is also a region that ensures controllability and breakdown tolerance during dynamic operation and supports the basic performance of the semiconductor device.

In processes or the like for manufacturing the Si semiconductor wafer which is the semiconductor substrate 51, when oxygen is introduced into the semiconductor wafer, the oxygen is donorized at a specific annealing temperature by a thermal donorization phenomenon, and the n-type impurity concentration C_{drift} of the n⁻-type drift layer 7 increases. In particular, in the case of an MCZ wafer, this increase is more pronounced than in a semiconductor wafer manufactured by the FZ method.

In the first preferred embodiment, in order to solve problems caused by this, when the maximum oxygen concentration of the semiconductor substrate 51 is set as maximum [Oᵢ], the following expression (1) is satisfied for maximum [Oᵢ].

maximum [Oᵢ]=9.40×10¹⁶×ln(C_{drift})−2.27×10¹⁸ (1)

In expression (1), [Oᵢ] is calculated by using a detected value obtained by detecting oxygen in Si by fourier transform infrared spectroscopy (FTIR) and a conversion coefficient adopted in American Society for Testing and Materials (ASTM) F121-79 (Old ASTM). The impurity concentration C_{drift} is, for example, a representative value (for example, average value, median value, etc.) of the n-type impurity concentration in the n⁻-type drift layer 7. The unit of [Oᵢ] is the same as the unit of the impurity concentration C_{drift} (for example, [cm⁻³]), and ln denotes a natural logarithm.

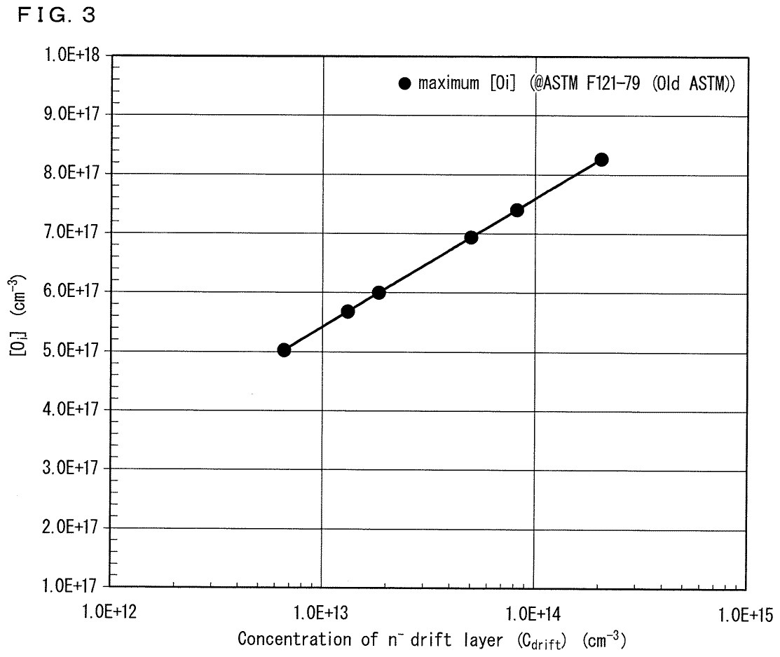

FIG. 3 is a graph illustrating a relationship between the oxygen concentration [Oᵢ] of the semiconductor substrate 51, which is an MCZ wafer, and the impurity concentration C_{drift} of the n⁻-type drift layer 7 in expression (1).

According to the configuration of the first preferred embodiment that satisfies this relationship, even when the impurity concentration C_{drift} of the n⁻-type drift layer 7 changes due to the thermal donorization phenomenon, it is possible to suppress adverse effects on the voltage (static withstand voltage) holding capability in the OFF state, which is a basic performance of the semiconductor device. In addition, it is possible to suppress adverse effects such as instability and variation in the impurity profile of the n⁻-type buffer layer 8 caused by oxygen. In particular, when the semiconductor substrate 51 is an MCZ wafer having a uniform oxygen concentration profile, the suppression of adverse effects is effective. The maximum [Oᵢ] can also be referred to as the limit value of [Oᵢ] for maintaining the voltage holding capability in the OFF state when the impurity concentration C_{drift} of the n⁻-type drift layer 7 changes due to oxygen-induced thermal donorization in the MCZ wafer.

As described above, the [Oᵢ] in expression (1) is calculated using the conversion coefficient of Old ASTM. When [Oᵢ] is calculated using the conversion coefficient of ASTM F121-83 (New ASTM), it is sufficient that the following expression (2) is satisfied. When [Oᵢ] is calculated using the conversion coefficient of International Oxygen Coefficient 1988 (IOC 88), it is sufficient that the following expression (3) is satisfied.

maximum [Oᵢ]=4.78×10¹⁶×ln(C_{drift})−1.16×10¹⁸ (2)

maximum [Oᵢ]=6.13×10¹⁶×ln(C_{drift})−1.48×10¹⁸ (3)

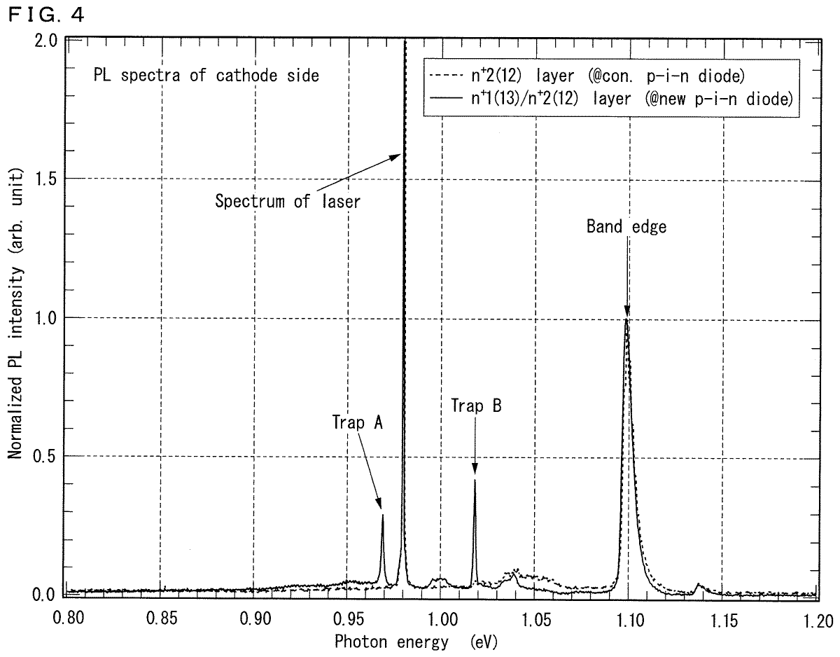

FIG. 4 is a graph illustrating PL spectra obtained by analysis using a photoluminescence (PL) method for each cathode structure of the diode of FIGS. 2A and 2B. The PL method is an analysis technique in which light is irradiated onto a semiconductor, and light emitted when electron-hole pairs recombine via defect levels is observed. The measurement conditions of FIG. 4 are that the wavelength of a He—Ne laser is 633 nm, the temperature is 30 K, the laser intensity incident on the sample surface is 4.5 mW, the laser diameter is 1.3 mm, and the laser intensity per unit area of the sample surface is 0.339 MW/cm².

In FIG. 4, the vertical axis is the PL intensity normalized by the intensity at the band edge of each layer. The PL intensity on the vertical axis of FIG. 4 corresponds to the defect density, and it is illustrated that the stronger the PL intensity, the higher the density of point defects from which the PL intensity originates. FIG. 4 illustrates PL spectra in which, in the n⁺-type cathode layer including the n⁺-type cathode layers 12 and 13 according to the first preferred embodiment, two characteristic intensity peaks (peak levels) are present. The two characteristic intensity peaks, that is, the two traps (trap A and trap B) of FIG. 4, are absent in the con. p-i-n diode of FIG. 2A in which the n⁺-type cathode layer 13 is absent, but are present in the new p-i-n diode of FIG. 2B in which the n⁺-type cathode layer 13 is present. Therefore, the n⁺-type cathode layer 13 contains point defects of the two traps (trap A and trap B), whereas the n⁺-type cathode layer 12 contains no point defects of the two traps (trap A and trap B). The photon energies of the point defects for which intensity peaks are detected by the photoluminescence method of FIG. 4 include 0.969 eV for trap A and 1.018 eV for trap B.

Trap A and trap B respectively correspond to the levels of CᵢCₛ (G center) and W center. The effects described in the first, second, and fifth preferred embodiments are derived from trap A and trap B detected by the PL method. Here, even when the n⁺-type cathode layer 13 contains point defects of only one trap B, rather than point defects of the two traps (trap A and trap B), the effects described in the first, second, and fifth preferred embodiments can still be obtained to some extent.

Here, the formation of the point defects of the two traps due to the reaction of impurities (oxygen and carbon) in Si will be briefly described. The specific method of manufacturing the n⁺-type cathode layer 13 containing the point defects of the two traps will be described in the seventh preferred embodiment.

First, in step A1, by performing ion implantation on the backside surface of the semiconductor substrate, vacancies (V) and Si interstitial pairs (I_{Si}) are formed as lattice defects. In step A2, through diffusion and self-aggregation of lattice defects, V₂ and W centers (I_{Si3} clusters) composed of Si interstitial pairs (I_{Si}) are formed. In step A3, simultaneously with step A2, a substitution reaction occurs between carbon (Cₛ) at lattice sites and Si interstitial pairs (I_{Si}), forming interstitial carbon (Cᵢ). In step A4, through diffusion of interstitial carbon (Cᵢ) and vacancies (V) which are lattice defects, reactions occur at room temperature among carbon (Cₛ) at lattice sites, interstitial carbon (Cᵢ), Si interstitial pairs (I_{Si}), and impurities (oxygen, carbon, hydrogen) in Si, forming G centers (composite defects CᵢCₛ as impurity defects). In step A5, crystallinity is restored to some extent by annealing treatment, but W centers (I_{Si3} clusters) composed of Si interstitial pairs and G centers (composite defects CᵢCₛ as impurity defects) remain.

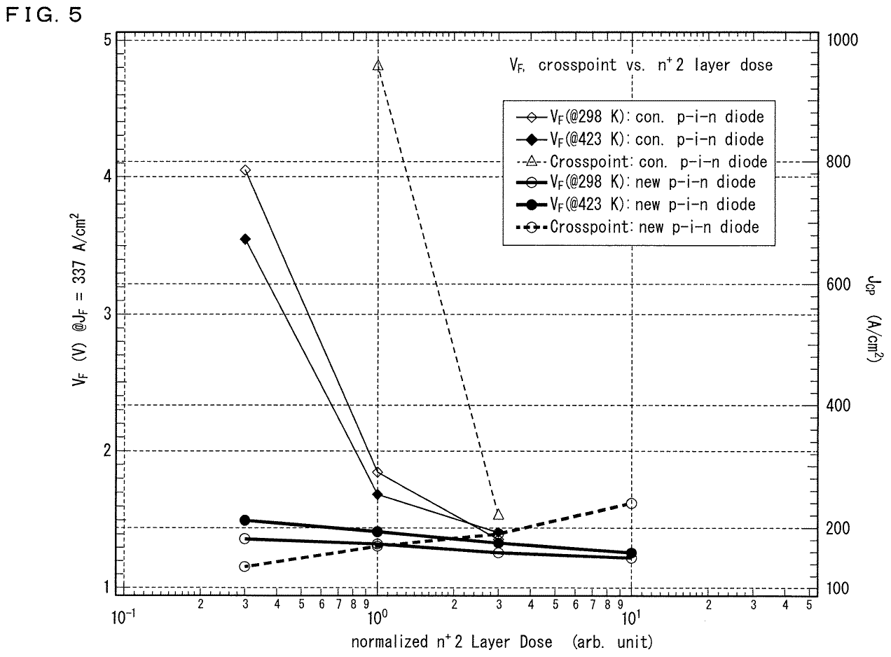

FIG. 5 is a graph illustrating a relationship between on-voltages (V_{F}) at 298 K and 423 K and the dose amount of the n⁺-type cathode layer 12 for the diode of FIGS. 2A and 2B. FIG. 5 also illustrates a relationship between a current density (J_{CP}) at the cross point of output characteristics at 298 K and 423 K and the dose amount of the n⁺-type cathode layer 12 for these diodes.

In the con. p-i-n diode of FIG. 2A, as illustrated in FIG. 5, as the dose amount of the n⁺-type cathode layer 12 decreases, the contact resistance between the second electrode 17 and the n⁺-type cathode layer 12 sharply increases, resulting in that the on-voltage (V_{F}) rises sharply. On the other hand, in the new p-i-n diode of FIG. 2B including the n⁺-type cathode layers 12 and 13, that is, in the diode according to the first preferred embodiment, the sharp rise in the on-voltage (V_{F}) can be suppressed as illustrated in FIG. 5, and the current density (J_{CP}) at the cross point can be reduced. Once the current density at the cross point is reduced, when the semiconductor device is incorporated into a module in a parallel state and is in an ON state, concentration of current in a specific chip can be suppressed, and the module performance of mounting the semiconductor device can be effectively enhanced.

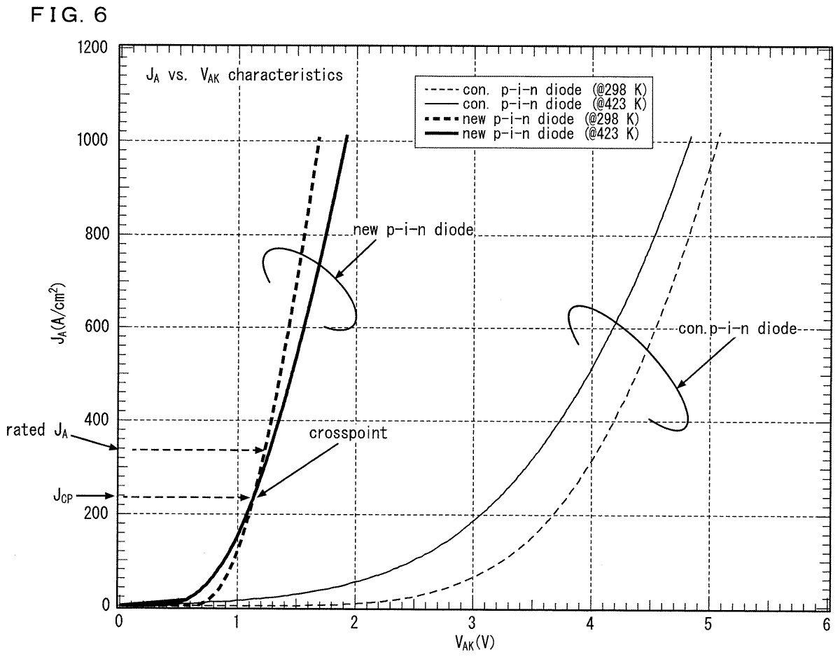

FIG. 6 illustrates the cross point when the dose amount of the n⁺-type cathode layer 12 is identical in the diode of FIGS. 2A and 2B. In the new p-i-n diode, the n⁺-type cathode layer 13 contains point defects of trap B, whereas the n⁺-type cathode layer 12 contains no point defects, and thus, as illustrated in FIG. 6, no adverse effect on the output characteristics of the diode is observed. In contrast, in the con. p-i-n diode, the output characteristics of the diode at 298 K and 423 K do not cross.

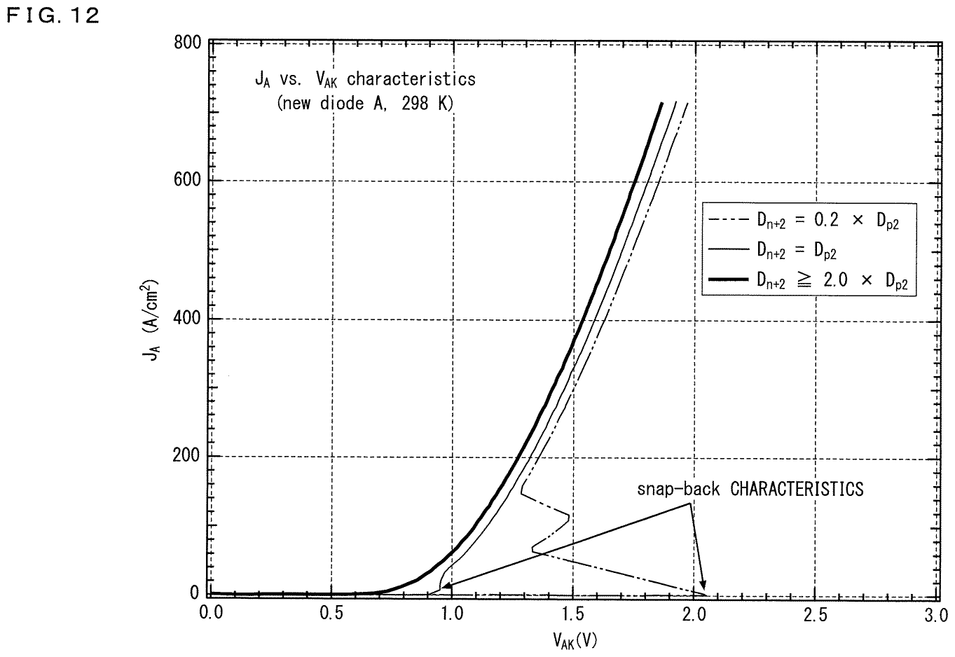

As the behavior of the output characteristics of the diode, it is preferable that (i) no snap-back characteristics appear, (ii) the output characteristics of the diode at low temperature and at high temperature cross each other as in the new p-i-n diode of FIG. 5, and (iii) the current density (J_{CP}) at the cross point is lower than the rated current density (rated J_{A}) which is the current density at the on-voltage (V_{F}). As illustrated by the results in FIGS. 5 and 6, according to the new p-i-n diode of FIG. 2B including the n⁺-type cathode layers 12 and 13, it is possible to satisfy (ii) and (iii), and thus, the output characteristics of the diode can be normalized. Note that satisfaction of (i) will be described with reference to FIG. 12 in the second preferred embodiment.

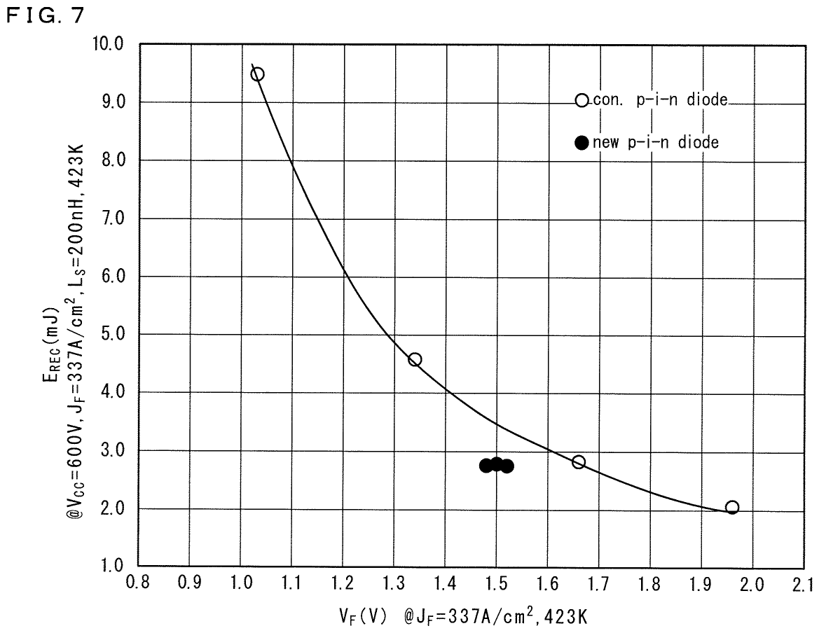

FIG. 7 is a graph illustrating a trade-off characteristic between a switching loss (E_{REC}) and the on-voltage (V_{F}) for the diode of FIGS. 2A and 2B. In consideration of the results illustrated in FIG. 5, the diode used as the con. p-i-n diode of FIG. 7 is one in which the dose amount of the n⁺-type cathode layer 12 is set to a dose amount that does not cause a sharp rise in the on-voltage (V_{F}).

As illustrated in FIG. 7, in the con. p-i-n diode, when carrier lifetime control by electron beams of charged particles is performed, a trade-off characteristic arises between the switching loss (E_{REC}) and the on-voltage (V_{F}). In contrast, in the new p-i-n diode, even without performing carrier lifetime control by electron beams of charged particles, it is possible to achieve control on the high-speed side (low E_{REC} and high V_{F}) as compared with the trade-off characteristic of the con. p-i-n diode illustrated in FIG. 7.

As described above, in the diode according to the first preferred embodiment, when the maximum oxygen concentration of the semiconductor substrate 51 calculated using the conversion coefficient of ASTM F121-79 (Old ASTM) is defined as maximum [Oᵢ] and the n-type impurity concentration of the n⁻-type drift layer 7 is defined as C_{drift}, maximum [Oᵢ]=9.40×10¹⁶×ln(C_{drift})−2.27×10¹⁸ is satisfied. With this configuration, for example, while securing sufficient withstand voltage holding capability in the OFF state, it is possible to implement normal ON operation and to enhance breakdown tolerance during dynamic operation.

In the first preferred embodiment, among the n⁺-type cathode layers 12 and 13, the n⁺-type cathode layer 13 contains point defects, whereas the n⁺-type cathode layer 12 contains no point defects. With this configuration, for example, normal ON operation and high-speed operation can be implemented for the cross point and the like, and the trade-off characteristic between the switching loss (E_{REC}) and the on-voltage (V_{F}) can be controlled toward the high-speed side.

As will be described later, the point defects contained in the n⁺-type cathode layer 13 can be generated during manufacturing of the semiconductor device without performing carrier lifetime control by charged particles. Therefore, this is particularly effective when the semiconductor substrate 51 is an MCZ wafer that is susceptible to the influence of impurities in the wafer due to carrier lifetime control by charged particles.

### Second Preferred Embodiment

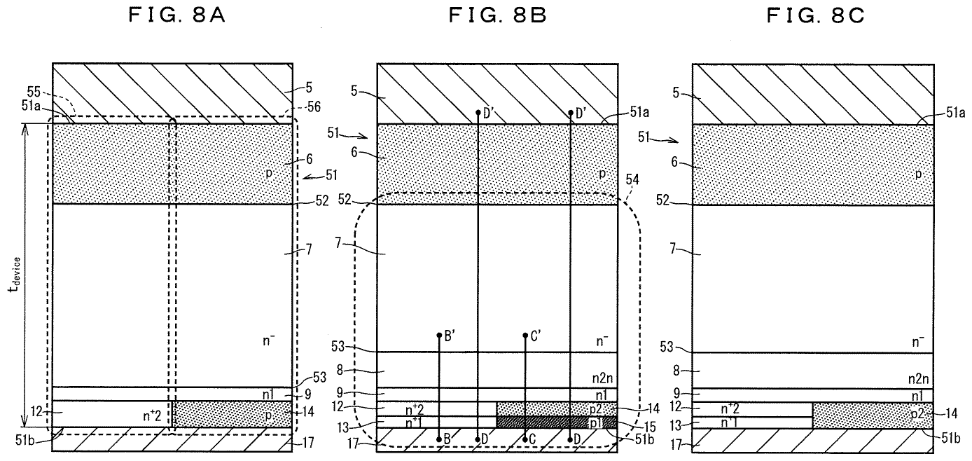

FIG. 8A is a cross-sectional view illustrating a configuration of a conventional diode (hereinafter, also referred to as “con. diode”). FIG. 8B is a cross-sectional view illustrating a configuration of a diode according to a second preferred embodiment (hereinafter, also referred to as “new diode A”). FIG. 8C is a cross-sectional view illustrating the configuration of the diode according to the second preferred embodiment (hereinafter, also referred to as “new diode B”).

The configuration of FIG. 8A is similar to the configuration of FIG. 2A with a p-type cathode layer 14 added thereto. The configuration of FIG. 8B is similar to the configuration of FIG. 2B with the p-type cathode layers 14 and 15 added thereto. The configuration of FIG. 8C is similar to the configuration of FIG. 2B with the p-type cathode layer 14 added thereto and without addition of the p-type cathode layer 15.

The p-type cathode layer 14, which is a third semiconductor layer, is provided adjacent to the n⁺-type cathode layer 12 between the n⁻-type drift layer 7 and the second electrode 17. The p-type cathode layer 14 has, for example, boron (B) as a p-type impurity, a peak impurity concentration of, for example, 1.0×10¹⁶ atoms/cm³ to 1.0×10¹⁸ atoms/cm³, and a depth from the back surface 51b of, for example, 0.3 μm to 0.5 μm.

The p-type cathode layer 15, which is a fourth semiconductor layer, is provided adjacent to the n⁺-type cathode layer 13 between the n⁻-type drift layer 7 and the second electrode 17 and is provided on the second electrode 17 side of the p-type cathode layer 14. The p-type cathode layer 15 has, for example, boron (B) or BF₂ as a p-type impurity, a peak impurity concentration of, for example, 1.0×10¹⁷ atoms/cm³ to 1.0×10¹⁹ atoms/cm³, and a depth from the back surface 51b of, for example, 0.1 μm to 0.2 μm.

In the new diode A of FIG. 8B, the n⁻-type drift layer 7, the n-type buffer layers 8 and 9, the n⁺-type cathode layers 12 and 13, and the p-type cathode layers 14 and 15 form the vertical structure 54. In the new diode B of FIG. 8C, the n⁻-type drift layer 7, the n-type buffer layers 8 and 9, the n⁺-type cathode layers 12 and 13, and the p-type cathode layer 14 form the vertical structure 54.

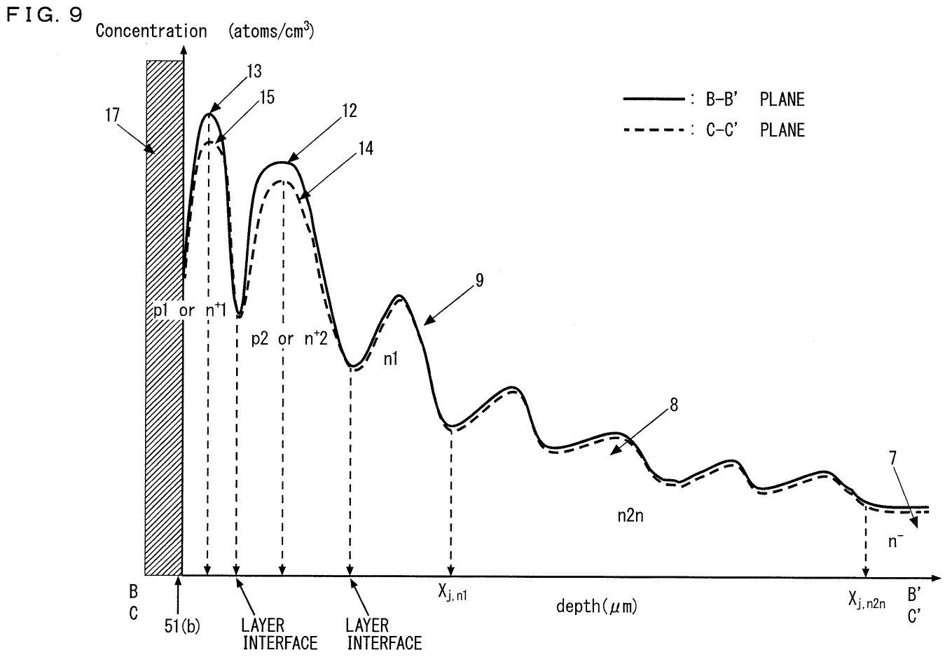

FIG. 9 is a graph illustrating impurity profiles in the depth direction taken along lines B-B′ and C-C′ in the new diode A of FIG. 8B. As illustrated in FIG. 9, in both impurity profiles along lines B-B′ and C-C′, the impurity concentration decreases toward the n⁻-type drift layer 7. The impurity concentration of the n-type buffer layer 8 may have a plurality of peaks.

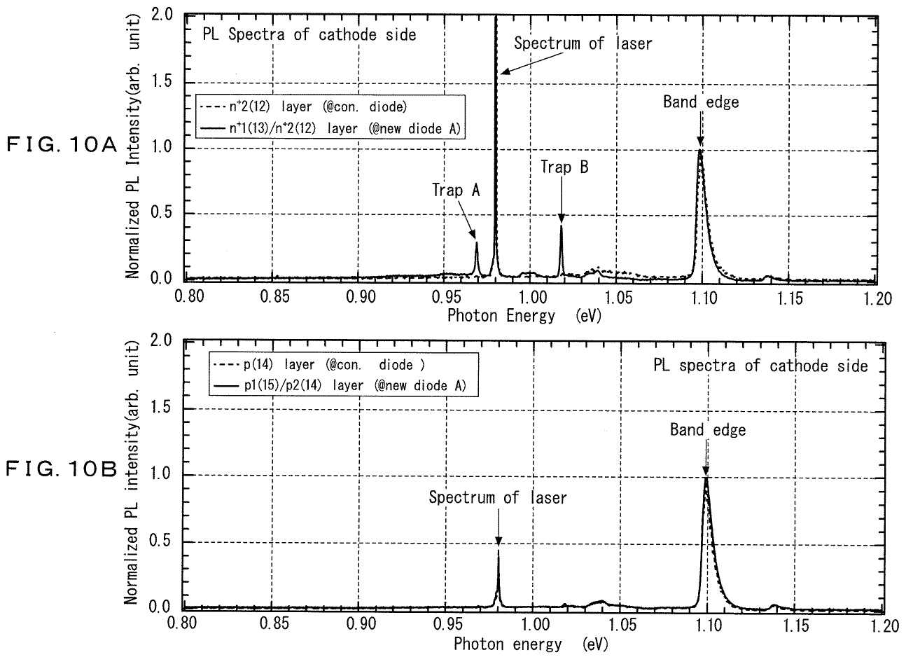

FIG. 10A is a graph illustrating PL spectra obtained when the respective n-type cathode structures (the n⁺-type cathode layers 12 and 13) of the diode of FIGS. 8A and 8B are analyzed by the PL method. FIG. 10B is a graph illustrating PL spectra obtained when the respective p-type cathode structures (the p-type cathode layers 14 and 15) of the diode of FIGS. 8A and 8B are analyzed by the PL method. The measurement conditions of FIGS. 10A and 10B are similar to the measurement conditions of FIG. 4 of the first preferred embodiment.

In FIGS. 10A and 10B, the vertical axis is the PL intensity normalized by the intensity at the band edge of each layer. From FIG. 10A, it is found that the n⁺-type cathode layer 13 contains point defects of the two traps (trap A and trap B), whereas the n⁺-type cathode layer 12 contains no point defects of the two traps (trap A and trap B). In addition, from FIG. 10B, it is found that the p-type cathode layers 14 and 15 contain no point defects of traps like those in the n⁺-type cathode layer 13.

Next, the improvement in performance and thermal stability of the diode achieved by the point defects contained in the n⁺-type cathode layer 13 will be described using a 1200 V class diode as an example.

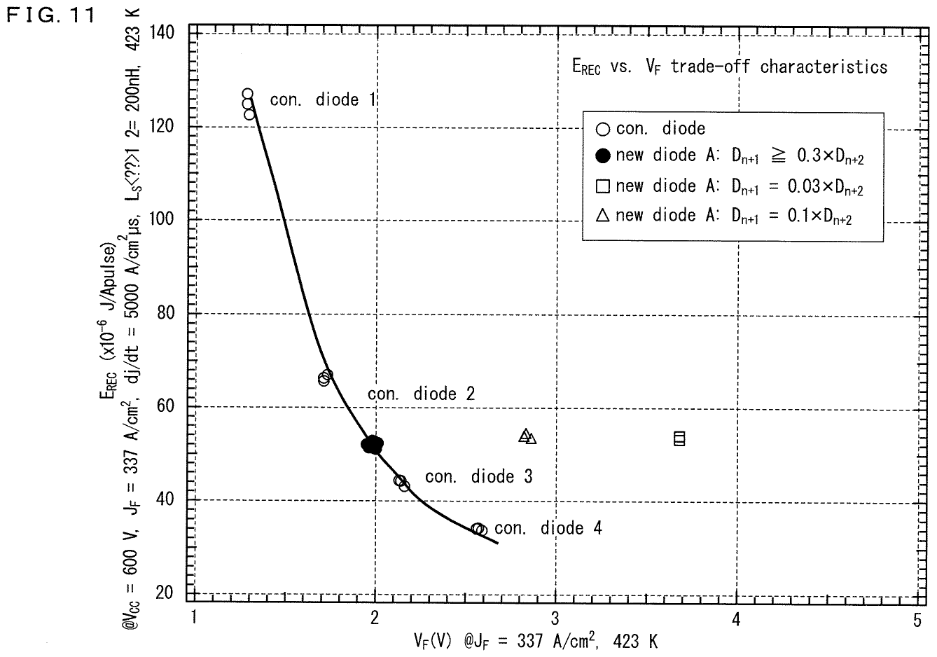

FIG. 11 is a graph illustrating the trade-off characteristic between the switching loss (E_{REC}) and the on-voltage (V_{F}) for the diode of FIGS. 8A and 8B. V_{AK} is a voltage between an anode and a cathode. In FIG. 11, with the dose amounts of the n⁺-type cathode layers 12 and 13 of FIG. 8B as parameters, trade-off characteristics of con. diodes 1, 2, and 3 and trade-off characteristics of 3 new diodes A are illustrated. It should be noted that the con. diode 1 is the con. diode of FIG. 8A in which carrier lifetime control by electron beams has not been performed. The con. diodes 2 and 3 are the con. diodes of FIG. 8A in which carrier lifetime control by electron beams has been performed.

In the new diode A of FIG. 8B, when the dose amounts per unit area of the n⁺-type cathode layer 12 and the n⁺-type cathode layer 13 are Dₙ₊₂ and Dₙ₊₁, respectively, the following expression (4) is satisfied.

Dₙ₊₁≥0.3×Dₙ₊₂ (4)

The dose amount per unit area (atoms/cm²) is a value obtained by integrating, in the depth direction of the diffusion layer, the number of atoms of the impurity per unit volume, and the dose amount per unit volume (atoms/cm³) is an analysis value by secondary ion mass spectrometry (SiMS).

According to such a configuration, the contact property of the second electrode 17 is improved, and when the diode is in an ON state, electron injection from the n⁺-type cathode layers 12 and 13 can be stabilized. Then, similarly to the first preferred embodiment, it is possible to control the trade-off characteristic toward the high-speed side (low E_{REC} and high V_{F}) without performing carrier lifetime control by electron beams of charged particles.

FIG. 12 is a graph illustrating an output characteristic at 298 K of the new diode A of FIG. 8B. In the manufacturing method described in the seventh preferred embodiment, there are cases where the p-layer is inverted to an n-layer to form the new diode A of FIG. 8B. In such cases, according to the second preferred embodiment, when the dose amounts per unit area of the n⁺-type cathode layer 12 and the p-type cathode layer 14 are Dₙ₊₂ and Dₚ₂, respectively, the following expression (5) is satisfied. According to such a configuration, it is possible that (i) no snap-back characteristics appear, as described in the first preferred embodiment, and it is possible to normalize the output characteristics of the diode.

Dₙ₊₂≥2.0×Dₚ₂ (5)

Next, the performance of the new diode A of FIG. 8B satisfying expressions (4) and (5) will be described.

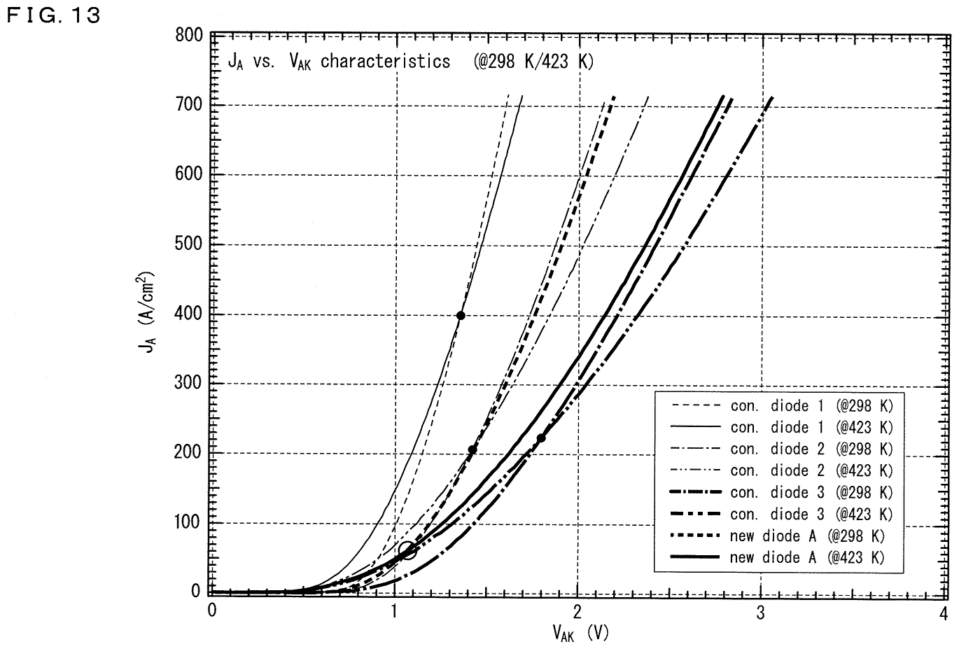

FIG. 13 is a graph illustrating output characteristics of the diode of FIGS. 8A and 8B. The con. diodes 1, 2, and 3 of FIG. 13 correspond to the con. diodes 1, 2, and 3 of FIG. 11. In the con. diode 1, carrier lifetime control by electron beams is not performed, whereas in the con. diodes 2 and 3, carrier lifetime control by electron beams is performed.

Regarding a cross point where the output characteristics at 298 K and 423 K cross, a white circle is attached to the cross point of the new diode A, that is, the diode according to the second preferred embodiment, and black circles are attached to the cross points of the con. diodes 1, 2, and 3. As illustrated in FIG. 13, in the new diode A, it is possible to reduce the current density at the cross point as compared with the con. diodes 2 and 3, in which the trade-off characteristic of FIG. 11 is close to the trade-off characteristic of the new diode A.

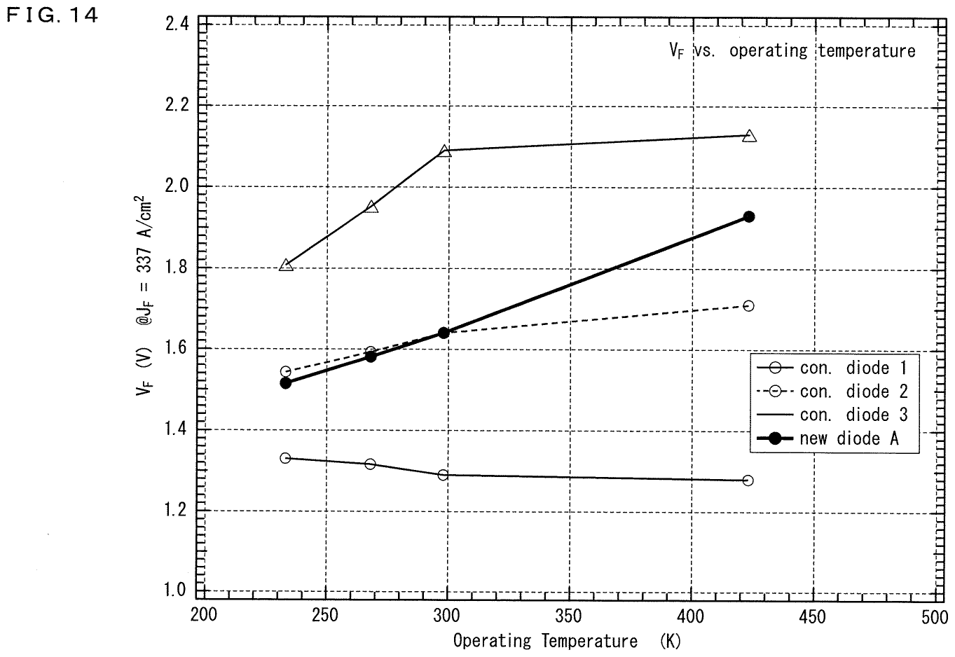

FIG. 14 illustrates an operation temperature dependency of the on-voltage (V_{F}). The operation temperature dependency of V_{F} of the new diode A tends to vary largely in the positive direction as compared with the operation temperature dependency of the con. diodes 1, 2, and 3. The operation temperature dependency of V_{F} of the con. diode 1, that is, the con. diode of FIG. 8A in which carrier lifetime control by electron beams is not performed, varies in the negative direction. The operation temperature dependency of the con. diodes 1, 2, and 3 varies due to the carrier lifetime control by the electron beams, and exhibits a behavior rate-limited by the temperature dependency of impurity defects generated by the electron beams. Here, the impurity defects refer to CᵢCₛ and CᵢOᵢ, and the CᵢOᵢ is a C center having a photon energy of 0.789 eV.

A chip of a power semiconductor device is ultimately mounted on a power module and incorporated into an inverter system. In order to minimize differences in the temperature of the chip itself during an ON operation when a plurality of chips operate in parallel, it is desirable that the current density at the cross point is low and that the operation temperature dependency of V_{F} is positive. Therefore, since the new diode A can satisfy these conditions, it is effective from the viewpoint of proper operation of the power module.

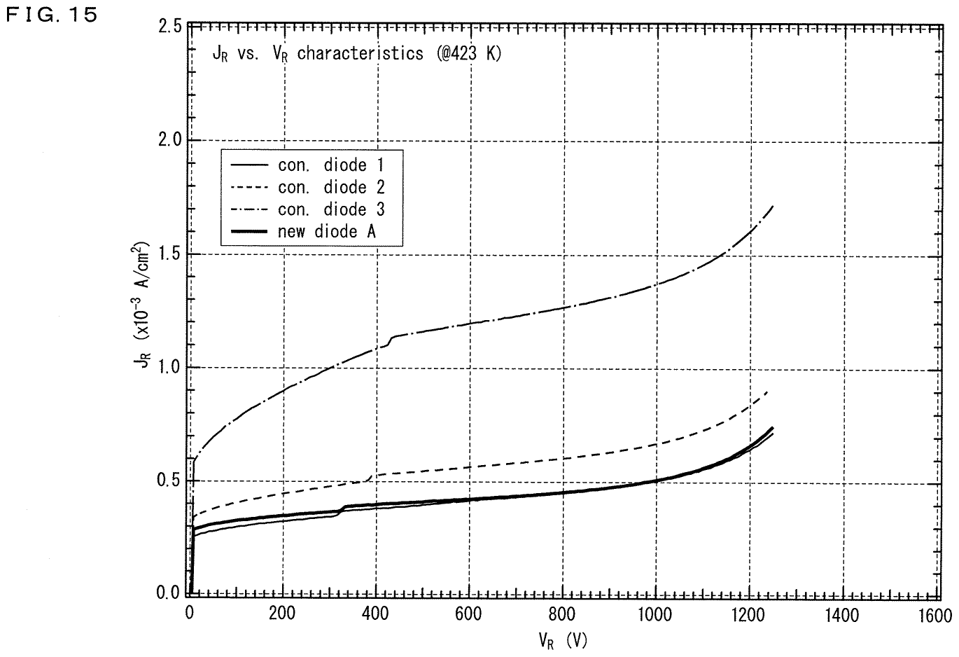

FIG. 15 is a graph illustrating leakage characteristics when a reverse bias is applied to the main junction 52 of the diode of FIGS. 8A and 8B. In the con. diodes 2 and 3, in which carrier lifetime control by electron beams is performed to control the trade-off characteristic of FIG. 11 toward the high-speed side, impurity defects (point defects) formed by the electron beams are also present in the n⁻-type drift layer 7, and thus, leakage current increases due to impurity defects present in the n⁻-type drift layer 7. As a result, off-state loss (J_{R}×V_{R}) when the semiconductor device holds voltage increases, causing problems in the thermal design of the power module and disadvantages in high-temperature operation.

In contrast, in the new diode A, the n⁺-type cathode layer 13 contains point defects, but no point defects are present in the n⁻-type drift layer 7, and no electron beam is used, and thus, no electron beam-induced impurity defects are present in the n⁻-type drift layer 7. Accordingly, in the new diode A, the leakage current is equivalent to that of the con. diode 1, that is, the con. diode of FIG. 8A in which carrier lifetime control by electron beams is not performed. Therefore, while achieving high-speed operation by means of point defects, it is possible to reduce leakage current, thereby enhancing stability in high-temperature operation and thermal stability.

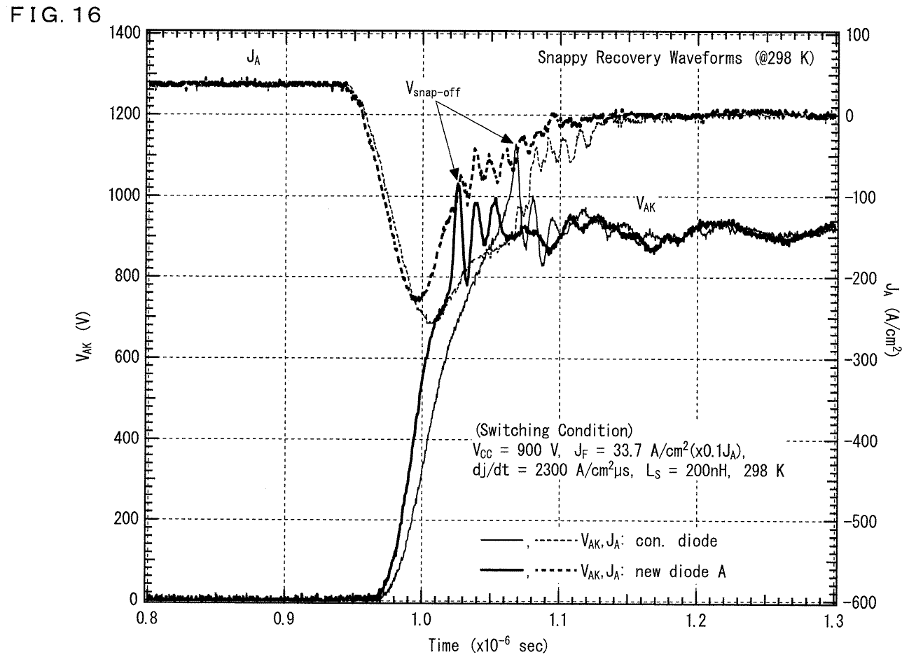

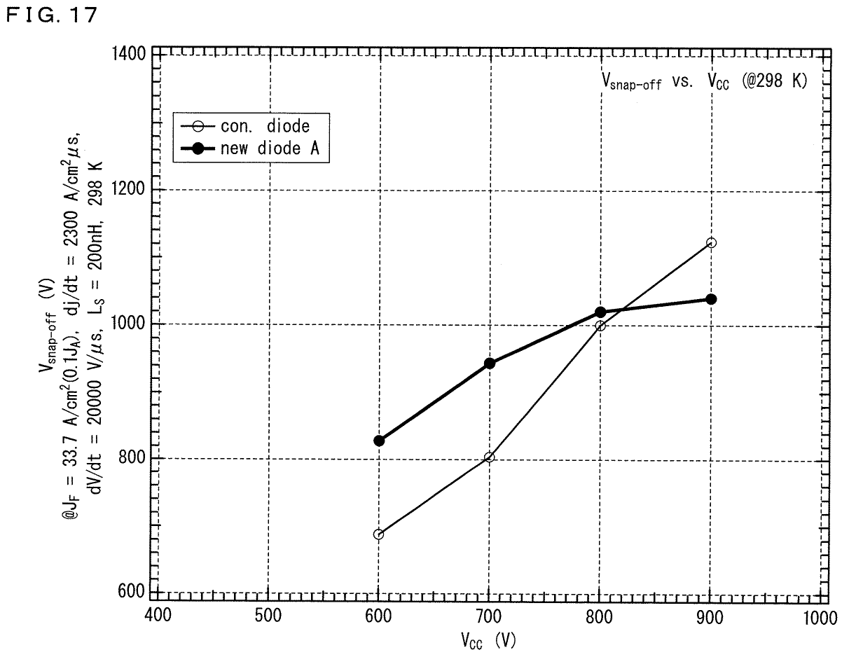

FIG. 16 is a graph illustrating a waveform during a recovery operation in a small-current mode of the diode illustrated in FIGS. 8A and 8B. Recovery operation in the small-current mode of a diode is also referred to as snappy recovery operation mode. FIG. 17 is a graph illustrating a relationship between a voltage (V_{snap-off}), which is a maximum V_{AK}, and a power supply voltage (V_{CC}), during the recovery operation of FIG. 16. In recovery operation, a diode in which V_{snap-off} is small and the dependency of V_{snap-off} on V_{CC} is insensitive can enhance the breakdown tolerance of the diode. Furthermore, in such a diode, V_{snap-off} can be easily controlled below the rated withstand voltage (in this example, 1200 V or lower because the diode is of the 1200 V class), and thus, destruction of the diode caused by the instantaneous rise of the voltage above the rated withstand voltage during recovery operation can be suppressed.

The tendency for V_{snap-off} to be large and for the dependency of V_{snap-off} on V_{CC} to be sensitive is pronounced in the con. diode 1, in which carrier lifetime control by electron beams is not performed, and thus, the con. diode 1 is used as the con. diode of FIGS. 16 and 17. As illustrated in FIG. 16, V_{snap-off} of the new diode A is smaller than V_{snap-off} of the con. diode, and, as illustrated in FIG. 17, the dependency of V_{snap-off} on V_{CC} of the new diode A is less sensitive than the dependency of V_{snap-off} on V_{CC} of the con. diode. Consequently, according to the new diode A, the breakdown tolerance can be enhanced.

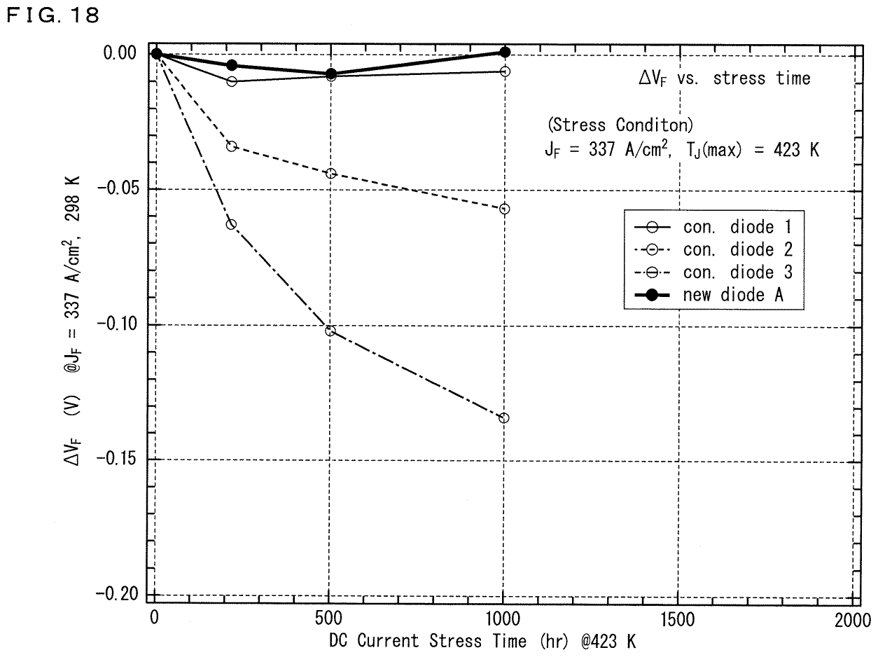

FIG. 18 is a graph illustrating a time-dependent change of the on-voltage (V_{F}) during a continuous conduction test for the diode of FIGS. 8A and 8B. In the con. diodes 2 and 3 in which carrier lifetime control by electron beams is performed, impurity defects (especially CᵢCₛ) generated by electron beams recover due to self-heating of the diode during conduction, resulting in a decrease in V_{F} during the continuous conduction test. In contrast, in the new diode A, carrier lifetime control by electron beams is not performed, and thus, a decrease in V_{F} due to self-heating of the diode during conduction can be suppressed, and the time-dependent change of the diode can be suppressed.

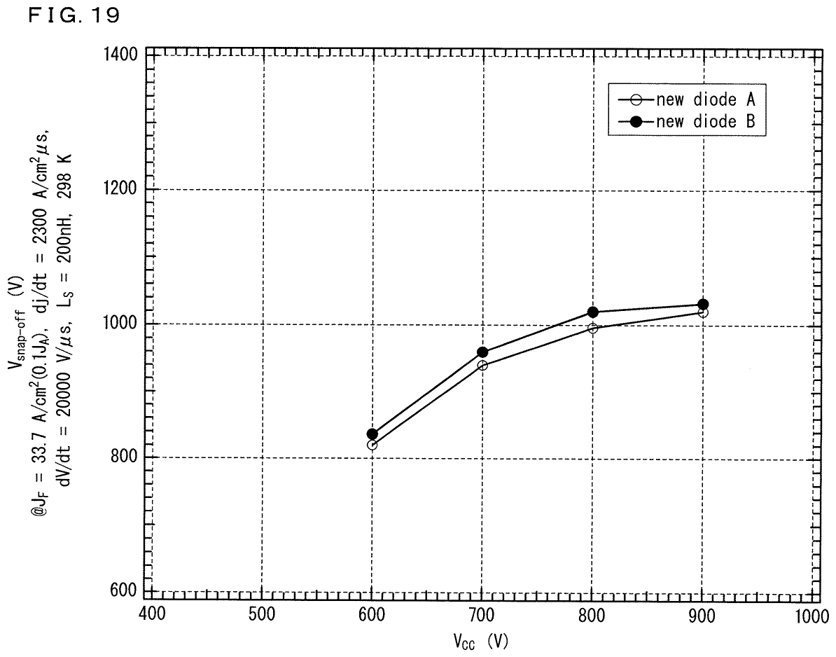

FIG. 19 is a graph, corresponding to FIG. 17, illustrating the relationship between V_{CC} and the maximum V_{AK} (voltage V_{snap-off}) during recovery operation in the small-current mode for the new diode A of FIG. 8B and the new diode B of FIG. 8C, both of which are the diodes according to the second preferred embodiment. As described above, the new diode B of FIG. 8C has a similar configuration as the new diode A of FIG. 8B except that the p-type cathode layer 15 is absent. As illustrated in FIG. 19, the dependency of V_{snap-off} on V_{CC} is insensitive in both the new diode A and the new diode B, and thus, the breakdown tolerance can be enhanced. Although a detailed description is omitted, the new diode B, in which the p-type cathode layer 14 is present while the p-type cathode layer 15 is absent, also provides similar effects as those of the new diode A with respect to FIGS. 11 to 15.

According to the diode of the second preferred embodiment described above, it is possible, without performing carrier lifetime control by electron beams, to control the trade-off characteristic between the switching loss (E_{REC}) and the on-voltage (V_{F}) toward the high-speed side, while achieving lower off-state loss, improved breakdown tolerance, and enhanced stability during the continuous conduction test at a high temperature. This is particularly effective when the semiconductor substrate 51 is an MCZ wafer that is susceptible to the influence of impurities in the wafer due to carrier lifetime control by charged particles.

### Third Preferred Embodiment

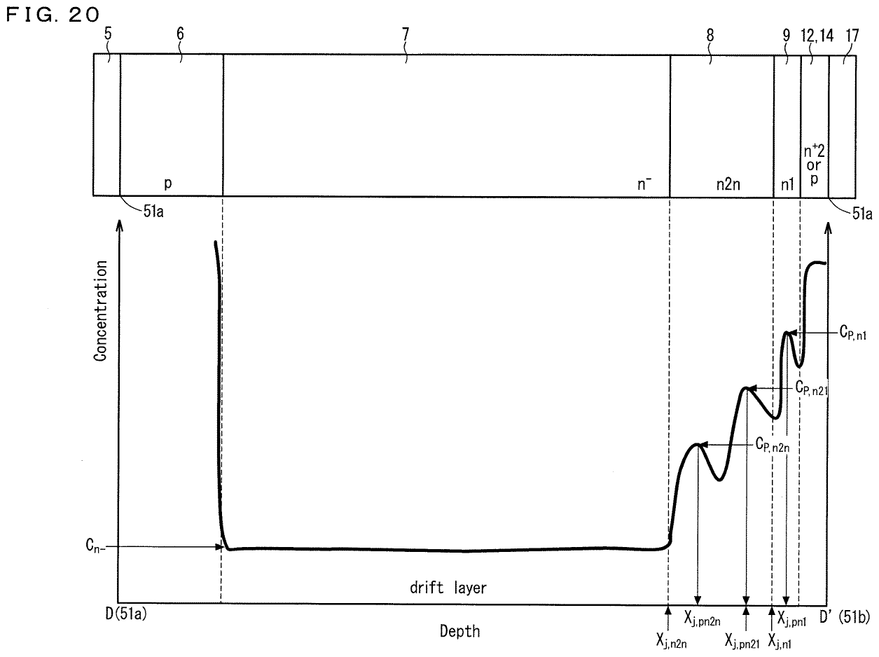

FIG. 20 is a diagram illustrating a configuration of a diode according to a third preferred embodiment and an impurity profile thereof. In the diode of the third preferred embodiment, the n⁺-type cathode layer 13 described heretofore is not essential, and the n-type buffer layer 8 and the n-type buffer layer 9 are used as the first semiconductor layer and the second semiconductor layer, respectively. The n-type buffer layer 8, which is the first semiconductor layer, contains point defects, whereas the n-type buffer layer 9, which is the second semiconductor layer provided on the second electrode 17 side of the n-type buffer layer 8, contains no point defects. By means of the n-type buffer layers 8 and 9, it is possible to achieve stabilization of the voltage holding capability in the OFF state, reduction of power consumption in the OFF state, and improvement in controllability and breakdown tolerance during dynamic operation.

The n-type buffer layer 9 has one peak impurity concentration C_{P,n1}. The n-type buffer layer 8 has, in order from the junction (X_{j,n1}) between the n-type buffer layer 8 and the n-type buffer layer 9 toward the junction (X_{j,n2n}) between the n-type buffer layer 8 and the n⁻-type drift layer 7, n peak impurity concentrations C_{P,n21}, C_{P,n22}, . . . C_{P,n2n}. The relationship of C_{p,2n}<. . . <C_{p,n22}<C_{p,n21}<C_{p,n1} is satisfied.

When the semiconductor substrate 51 is an MCZ wafer, thermal donorization caused by the oxygen concentration [Oᵢ] in Si may broaden the impurity profile within the n-type buffer layer 8. Note that broadening of the profile means that the impurity concentration is substantially constant between adjacent peaks of FIG. 20.

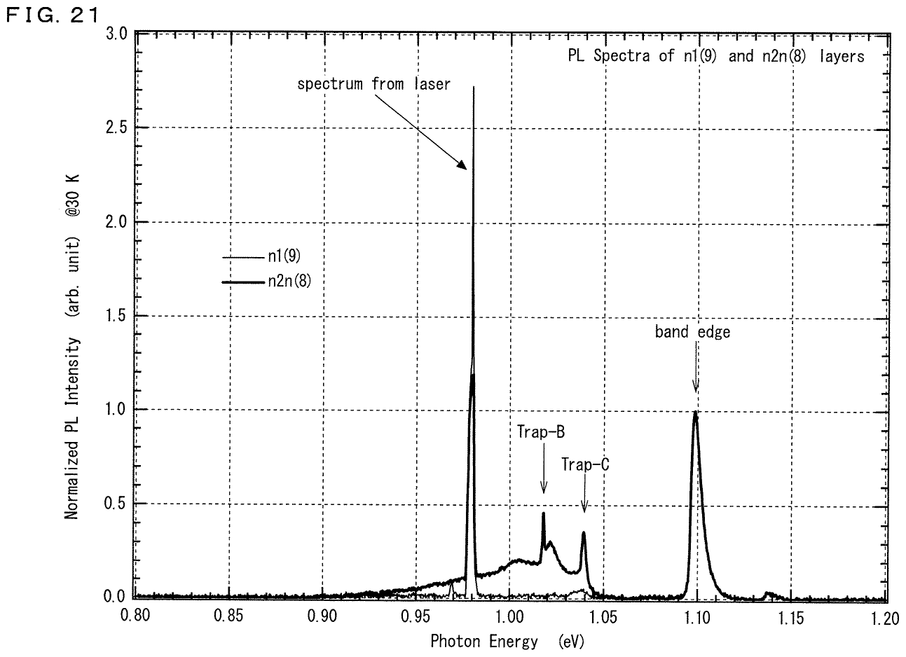

FIG. 21 is a graph illustrating the PL spectra obtained when the buffer structure (the n-type buffer layers 8 and 9) of the diode according to the third preferred embodiment is analyzed by the PL method. The measurement conditions of FIG. 21 are similar to the measurement conditions of FIG. 4 of the first preferred embodiment.

In FIG. 21, the vertical axis is the PL intensity normalized by the intensity at the band edge of each layer. From FIG. 21, it is found that the n-type buffer layer 8 contains point defects of two traps (trap B and trap C), whereas the n-type buffer layer 9 contains no point defects of the two traps (trap B and trap C). The photon energies of the point defects whose intensity peaks are detected by the photoluminescence method of FIG. 21 include 1.018 eV for trap B and 1.040 eV for trap C.

The energies of trap B and trap C correspond to the levels of the W center and the X center, respectively. The carrier lifetime of the n⁻-type drift layer 7, the n-type buffer layer 8, and the n-type buffer layer 9 may satisfy the relational expression described in the sixth preferred embodiment.

Next, the improvement in the performance and thermal stability of the diode achieved by the point defects contained in the n-type buffer layer 8 will be described using a 1200 V class diode as an example.

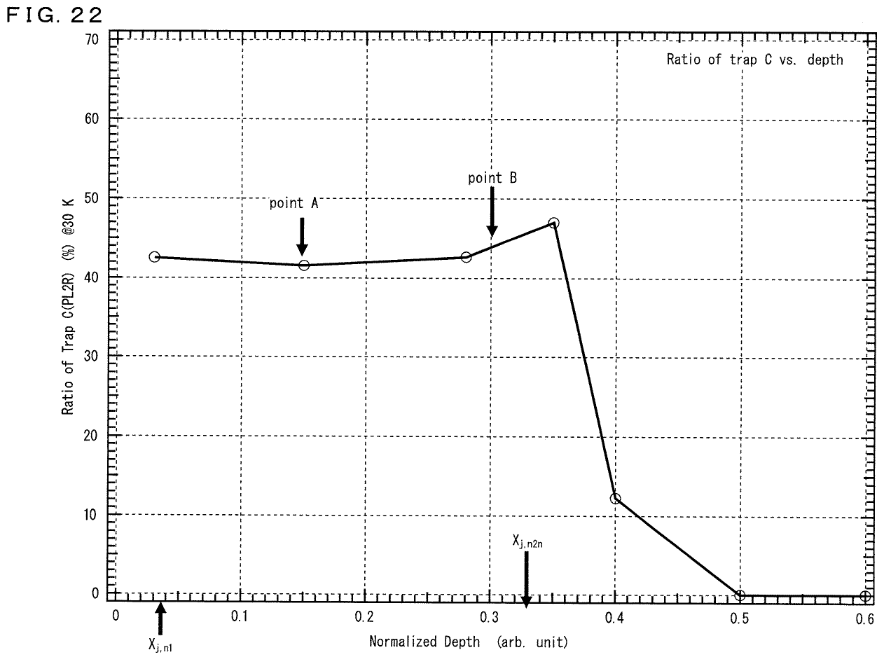

FIG. 22 is a graph illustrating the relationship between a PL2R ratio of the PL intensity of trap C and the depth of the n-type buffer layer 8. The PL2R ratio of the PL intensity of trap C is expressed by the following expression (6) when the intensity peak of trap B whose photon energy is 1.018 eV is defined as PL1 and the intensity peak of trap C whose photon energy is 1.040 eV is defined as PL2.

PL2R=PL2/(PL1+PL2)×100 (6)

In FIG. 22, the horizontal axis is the value obtained by normalizing the device thickness with t_{device} of FIG. 8A. As illustrated in FIG. 22, the PL2R ratio changes when the depth of the n-type buffer layer 8 changes, and thus, the PL2R ratio is hereinafter described as the PL2R ratio near the center in the thickness direction of the n-type buffer layer 8.

When the con. diode, which does not have the n-type buffer layer 8 of FIG. 8A, is provided together with a transistor, there is a breakdown mode in which a huge tail current appears in the latter half of the recovery operation, and the semiconductor device is destroyed by this tail current. This breakdown mode includes the following steps A11 to A14.

First, in step A11, for each of a p-i-n diode region 55 of the con. diode and a p-n-p Tr region 56 in which the transistor is provided, there is an operation time that rate-limits the operation. During the recovery operation, the operation of the p-i-n diode region 55 converges, and the operation of the p-n-p Tr region 56 is rate-limited. In step A12, on the p-type cathode side, hole injection is promoted to raise the carrier concentration, and while the electric field on the cathode side is relaxed, the electric field strength at the main junction 52 increases, thereby promoting impact ionization.

In step A13, electrons generated by the impact ionization promoted at the main junction 52 are injected into the n⁻-type drift layer 7, causing an increase in the base current of the transistor in the p-n-p Tr region 56, and a huge tail current appears in the recovery waveform. In step A14, simultaneously with the generation of the huge tail current, the transistor in the p-n-p Tr region 56 begins to operate, and thus, the semiconductor device cannot be controlled and the semiconductor device is destroyed. Note that even in the new diode A having the n-type buffer layer 8 of FIG. 8B, the above breakdown mode will occur unless the balance of trap B and trap C in the n-type buffer layer 8, and hence the PL2R ratio of the PL intensity of trap C of expression (6), are properly controlled.

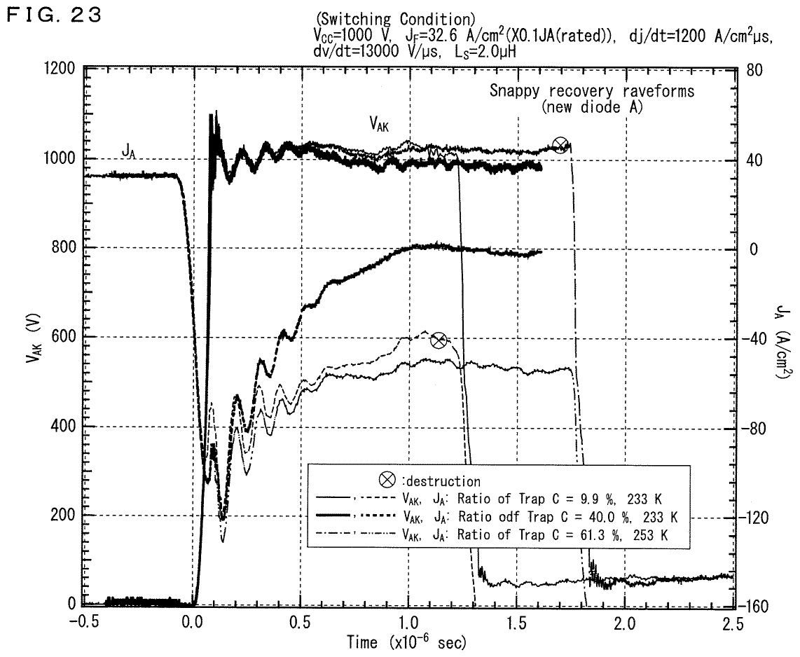

FIG. 23 is a graph illustrating a snappy recovery waveform at a low temperature for various PL2R ratios. When the PL2R ratio is 40.0%, the increase in the tail current in the latter half of the recovery operation is suppressed even at a low temperature of 233 K, so that no destruction occurs, and thus, the recovery operation can be blocked without increasing a reverse recovery charge amount (Q_{RR}). This is believed to be because the two traps (trap B and trap C) whose balance has been optimized contribute to accelerated carrier recombination, thereby eliminating the carrier plasma layer remaining on the cathode side, suppressing the rise in electric field strength at the main junction 52, and extending the depletion layer toward the cathode side, so that the recovery operation proceeds without the occurrence of the mode of step A13.

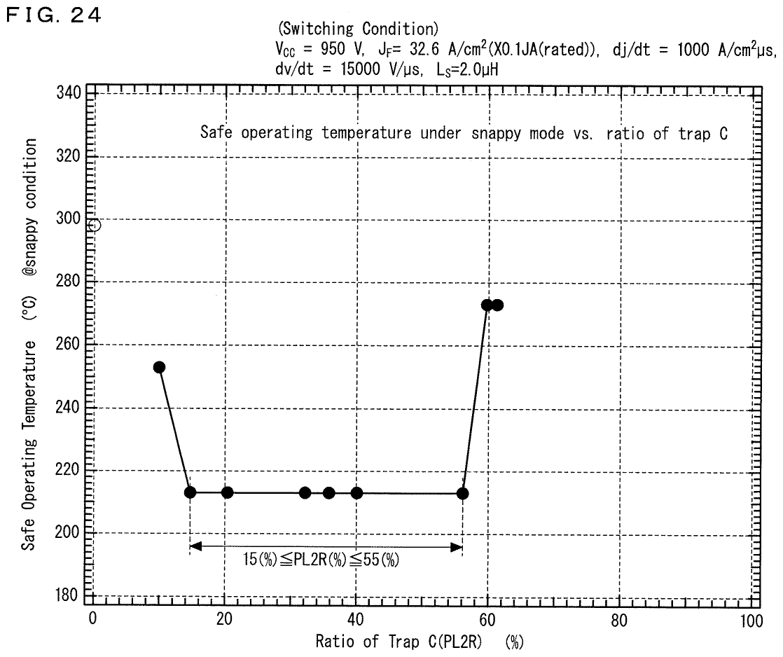

FIG. 24 is a graph illustrating a relationship between a safe operating temperature range and a PL2R ratio of the PL intensity of trap C during a snappy recovery operation of the diode of FIG. 20. When 15(%)≤PL2R (%)≤55(%) is satisfied, that is, when the PL2R ratio (%) is in a range of 15(%) to 55(%), inclusive, it is possible to block the recovery operation even at a low temperature of 213 K, and to expand the operating temperature range toward a low temperature side.

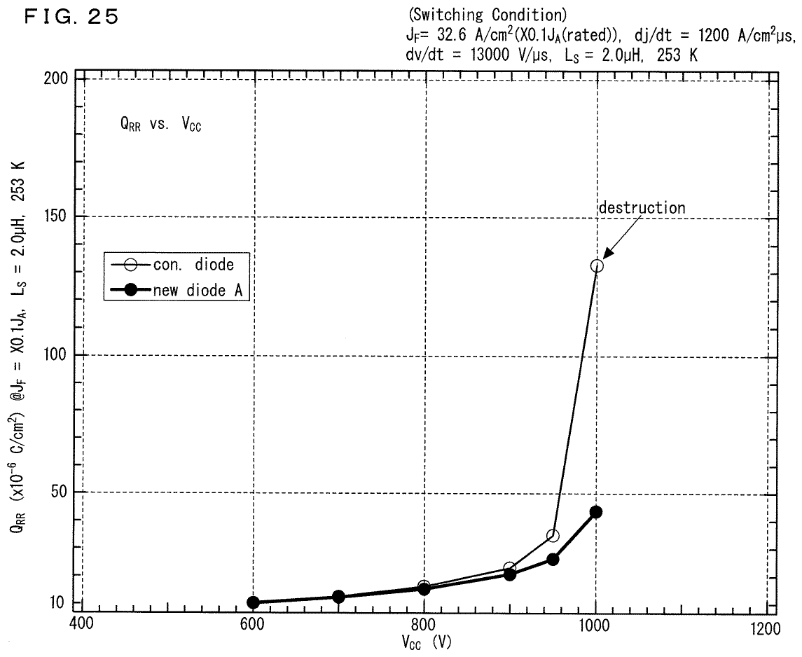

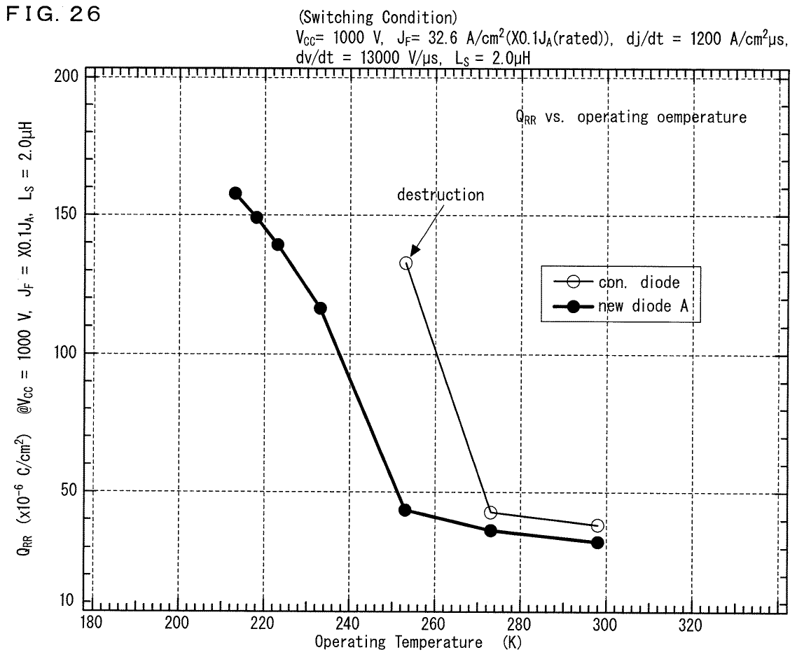

FIG. 25 is a graph illustrating a relationship between Q_{RR} and the power supply voltage (V_{CC}) during recovery operation, focusing on the destruction phenomenon caused by the huge tail current of FIG. 23, for the con. diode of FIG. 8A and the new diode A of FIG. 8B. In the new diode A of FIG. 8B in the following description, the n-type buffer layer 8 contains point defects, whereas the n-type buffer layer 9 contains no point defects. FIG. 26 is a graph illustrating a relationship between Q_{RR} and the operating temperature during recovery operation, focusing on the destruction phenomenon, for the con. diode of FIG. 8A and the new diode A of FIG. 8B.

As illustrated in FIGS. 25 and 26, the new diode A has a lower dependency of Q_{RR} on V_{CC} and the operating temperature as compared with the con. diode. That is, according to the new diode A, operation of the transistor of the p-n-p Tr region, which causes an increase in Q_{RR}, is suppressed, and durability during dynamic operation of the FWD is enhanced. This is believed to be because two traps (trap B and trap C) whose balance has been optimized promote recombination of carriers in the latter half of the recovery operation.

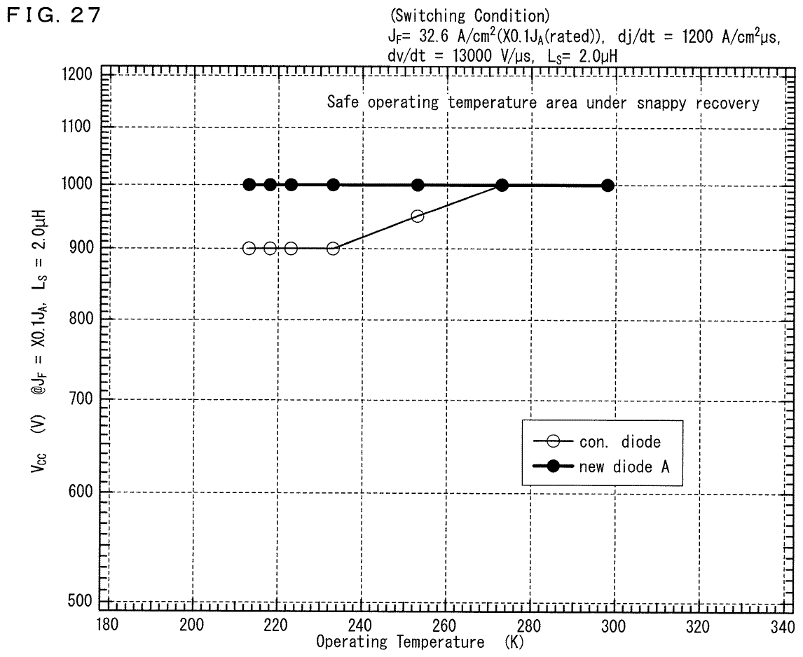

FIG. 27 illustrates a relationship between a blockable temperature and V_{CC} in a snappy recovery operation mode for the con. diode of FIG. 8A and the new diode A of FIG. 8B, which are of the 1200 V class. As illustrated in FIG. 27, according to the new diode A in which the n-type buffer layer 8 contains point defects of two traps (trap B and trap C), it is possible to expand a safe operating area (SOA) toward a higher V_{CC} side on a low temperature side which is at 253 K or lower.

According to the third preferred embodiment described above, the n-type buffer layer 8 contains point defects, the n-type buffer layer 9 contains no point defects, and the PL2R ratio (%) of the PL intensity of trap C is controlled to be in the range of 15(%) to 55(%), inclusive. With such a configuration, without performing carrier lifetime control by electron beams, it is possible to improve the capability of normally maintaining an ON operation even at a low temperature, the withstand voltage holding capability with low off-state loss that does not cause thermal runaway even at a high temperature, and the breakdown tolerance under dynamic operation. This is particularly effective when the semiconductor substrate 51 is an MCZ wafer that is susceptible to the influence of impurities in the wafer due to carrier lifetime control by charged particles.

### Fourth Preferred Embodiment

In the third preferred embodiment described above, a case has mainly been described in which the semiconductor device including the n-type buffer layer 8 containing point defects and the n-type buffer layer 9 containing no point defects is a diode. In a fourth preferred embodiment, a case will be described in which the semiconductor device is an IGBT.

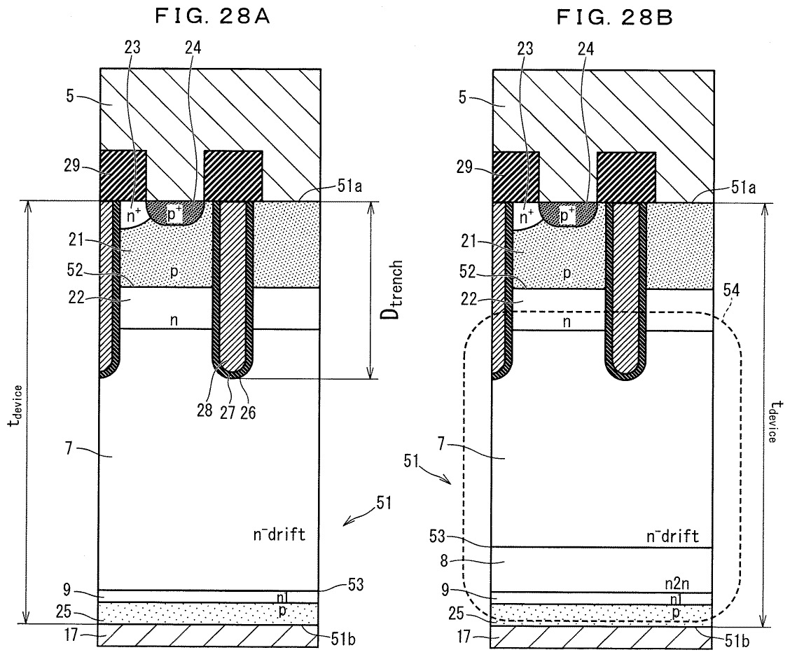

FIG. 28A is a cross-sectional view illustrating a configuration of a conventional IGBT (hereinafter, also referred to as “con. IGBT”). FIG. 28B is a cross-sectional view illustrating a configuration of an IGBT according to the fourth preferred embodiment (hereinafter, also referred to as “new IGBT”). It should be noted that the semiconductor substrate 51 of the new IGBT of FIG. 28B includes the n-type buffer layer 8, whereas the semiconductor substrate 51 of the con. IGBT of FIG. 28A does not include the n-type buffer layer 8.

The new IGBT of FIG. 28B includes the semiconductor substrate 51, the first electrode 5, a gate oxide film 27 which is a gate insulating film, a gate electrode 28, an interlayer film 29, and the second electrode 17. A final device thickness (t_{device}) corresponding to the thickness of the semiconductor substrate 51 is, for example, 40 μm to 700 μm.

The semiconductor substrate 51 includes the n⁻-type drift layer 7 which is a drift layer, the n-type buffer layer 8 which is the first semiconductor layer, the n-type buffer layer 9 which is the second semiconductor layer, a p-type base layer 21 which is a base layer, an n-type layer 22, an n⁺-type emitter layer 23 which is an emitter layer, a p⁺-type layer 24, and a p-type collector layer 25 which is the third semiconductor layer.

The n⁻-type drift layer 7 is similar to the n⁻-type drift layer 7 according to the first preferred embodiment, and, for example, the impurity concentration C_{drift} of the n⁻-type drift layer 7 is 1.0×10¹² atoms/cm³ to 5.0×10¹⁴ atoms/cm³.

The n-type buffer layer 9 is provided between the n⁻-type drift layer 7 and the second electrode 17, and is provided on the second electrode 17 side of the n-type buffer layer 8. The n-type buffer layer 9 has, for example, arsenic (As) or phosphorus (P) as an n-type impurity, with a maximum peak impurity concentration (C_{P,n1}) of, for example, 1.0×10¹⁵ atoms/cm³ to 5.0×10¹⁶ atoms/cm³, and a depth (X_{j,pn1}) from the back surface 51b of, for example, 1.0 μm to 5.0 μm.

The n-type buffer layer 8 is provided between the n⁻-type drift layer 7 and the n-type buffer layer 9. The n-type impurity concentration of the n-type buffer layer 8 is smaller than the n-type impurity concentration of the n-type buffer layer 9 and greater than the n-type impurity concentration of the n⁻-type drift layer 7. The n-type buffer layer 8 has, for example, proton (H⁺) as an n-type impurity, with a maximum peak impurity concentration (C_{p,n2n}) of, for example, less than C_{P,n1} of the n-type buffer layer 9, and preferably 0.01×C_{P,n1} or less, and a depth (X_{j,pn2}) from the back surface 51b of, for example, 20 μm to 30 μm deeper than the depth (X_{j,pn1}) of the n-type buffer layer 9.

In the fourth preferred embodiment as well, similarly to the third preferred embodiment, the n-type buffer layer 8 contains point defects, whereas the n-type buffer layer 9 contains no point defects. The PL2R ratio (%) of the PL intensity of trap C is in the range of 15(%) to 55(%), inclusive.

The p-type base layer 21 is provided between the first electrode 5 and the n⁻-type drift layer 7. The p-type base layer 21 has, for example, boron (B) as a p-type impurity, with a peak impurity concentration of, for example, 1.0×10¹⁶ atoms/cm³ to 1.0×10¹⁸ atoms/cm³, and a depth from the front surface 51a that is deeper than the n⁺-type emitter layer 23 and shallower than the n-type layer 22.

The n-type layer 22 is provided between the p-type base layer 21 and the n-type drift layer 7. The n-type layer 22 has, for example, arsenic (As) or phosphorus (P) as an n-type impurity, with a peak impurity concentration of, for example, 1.0×10¹⁵ atoms/cm³ to 1.0×10¹⁷ atoms/cm³ and a depth from the front surface 51a that is, for example, 0.5 μm to 1.0 μm deeper than the p-type base layer 21.

The n⁺-type emitter layer 23 is provided between the first electrode 5 and the p-type base layer 21. The n⁺-type emitter layer 23 has, for example, arsenic (As) or phosphorus (P) as an n-type impurity, with a peak impurity concentration of, for example, 1.0×10¹⁸ atoms/cm³ to 1.0×10²¹ atoms/cm³, and a depth from the front surface 51a of, for example, 0.2 μm to 1.0 μm.

The p⁺-type layer 24 is provided between the first electrode 5 and the p-type base layer 21. The p⁺-type layer 24 has, for example, boron (B) as a p-type impurity, with a surface impurity concentration of, for example, 1.0×10¹⁸ atoms/cm³ to 1.0×10²¹ atoms/cm³, and a depth from the front surface 51a that is the same as or deeper than the depth of the n⁺-type emitter layer 23.

The p-type collector layer 25 is provided between the n-type buffer layer 9 and the second electrode 17. The p-type collector layer 25 has, for example, boron (B) as a p-type impurity, with a peak impurity concentration of, for example, 1.0×10¹⁶ atoms/cm³ to 1.0×10²⁰ atoms/cm³, and a depth from the back surface 51b of, for example, 0.3 μm to 0.8 μm.

The n⁻-type drift layer 7, the n-type buffer layers 8 and 9, and the p-type collector layer 25 form the vertical structure 54.

The semiconductor substrate 51 of the IGBT is provided with a trench 26 penetrating through the p-type base layer 21, the n-type layer 22, and the n⁺-type emitter layer 23. The depth D_{trench} of the trench 26 from the front surface 51a is, for example, 2.0 μm or more, and is deeper than the n-type layer 22.

The gate electrode 28 is provided inside the trench 26 via the gate oxide film 27. The gate electrode 28 is electrically connected to the surface gate wiring portion 4a of FIG. 1 and is insulated from the first electrode 5 at emitter potential by the interlayer film 29 that includes an oxide film and the like. The gate trench structure in which the gate oxide film 27 and the gate electrode 28 are provided in the trench 26 can form a channel in the p-type base layer 21 through which the main current can flow when a voltage equal to or greater than a threshold voltage is applied to the gate electrode 28.

It is also possible to provide a dummy trench structure having a dummy electrode by replacing the gate electrode 28 of some gate trench structures with the dummy electrode connected to the first electrode 5 at emitter potential. When a dummy trench structure is provided, through suppression of the saturation current density and control of the capacitance characteristics of the IGBT, suppression of oscillation in a no-load short-circuit state and improvement of short-circuit withstand capability can be expected, and reduction of the on-voltage can be expected through an increase in the carrier concentration on the emitter side.

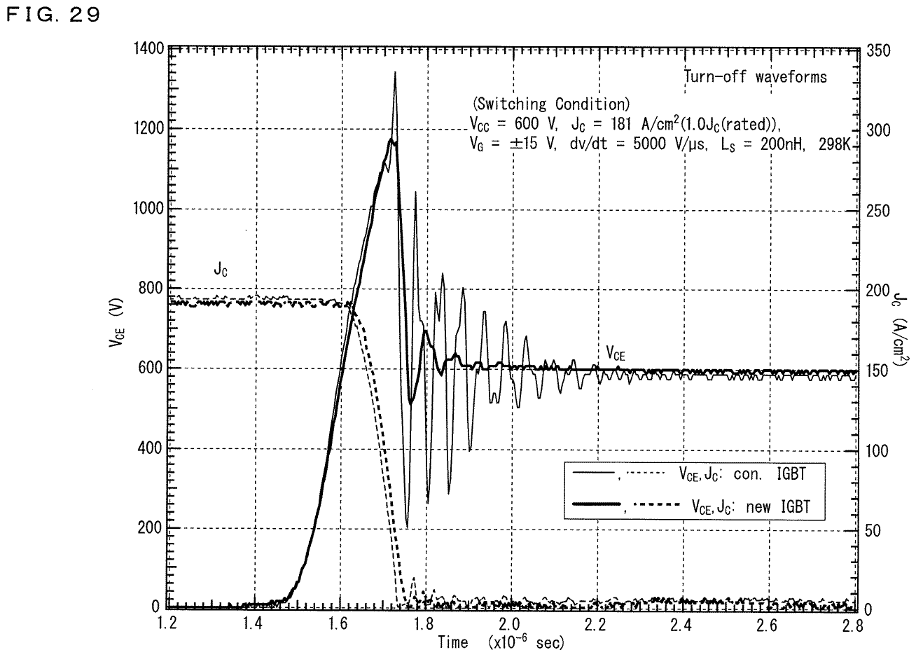

FIG. 29 is a graph illustrating turn-off waveforms at 298 K for the con. IGBT of FIG. 28A and the new IGBT of FIG. 28B, which are of the 1200 V class. The device thickness t_{device} of each IGBT is the same, and the impurity concentration C_{drift} of the n⁻-type drift layer 7 of each IGBT is the same.

In the new IGBT, that is, the IGBT according to the fourth preferred embodiment, a carrier plasma layer remains on the collector side during the latter half of the turn-off operation. As a result, the new IGBT mitigates the electric field intensity on the collector side. Consequently, as illustrated in FIG. 29, it is possible to suppress the snap-off observed in the con. IGBT and also suppress the oscillation phenomenon after snap-off, thereby achieving a turn-off operation with excellent controllability.

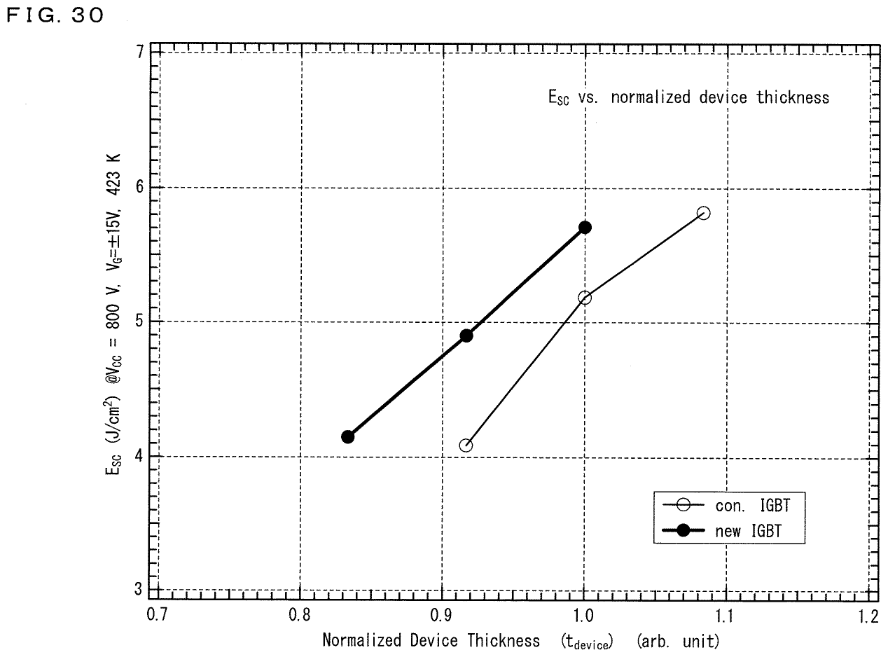

FIG. 30 is a graph illustrating a relationship between a maximum blockable energy density (E_{SC}) during a short circuit and the final device thickness (t_{device}). In the new IGBT, the SOA in a short-circuit state can be expanded compared to the con. IGBT, making it possible to reduce the device thickness t_{device} while ensuring a sufficient SOA.

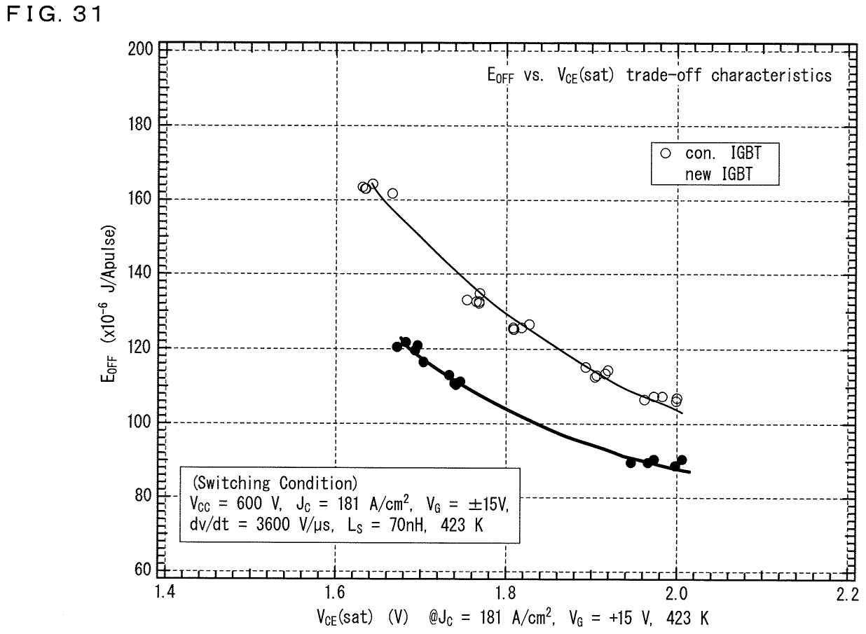

FIG. 31 is a graph illustrating a trade-off characteristic between a switching loss (E_{OFF}) and an on-voltage (V_{CE}(sat)) for the con. IGBT of FIG. 28A and the new IGBT of FIG. 28B, which are of the 1200 V class. In the new IGBT, the total loss can be reduced compared to the con. IGBT.

As described above, according to the IGBT including the n-type buffer layer 8 containing point defects and the n-type buffer layer 9 containing no point defects, in which the PL2R ratio (%) of the PL intensity of trap C is in the range of 15(%) to 55(%), inclusive, it is possible to achieve excellent controllability during dynamic operation and improve durability as illustrated in FIG. 29, reduce the device thickness t_{device} as illustrated in FIG. 30, and reduce the total loss as illustrated in FIG. 31.

### Fifth Preferred Embodiment

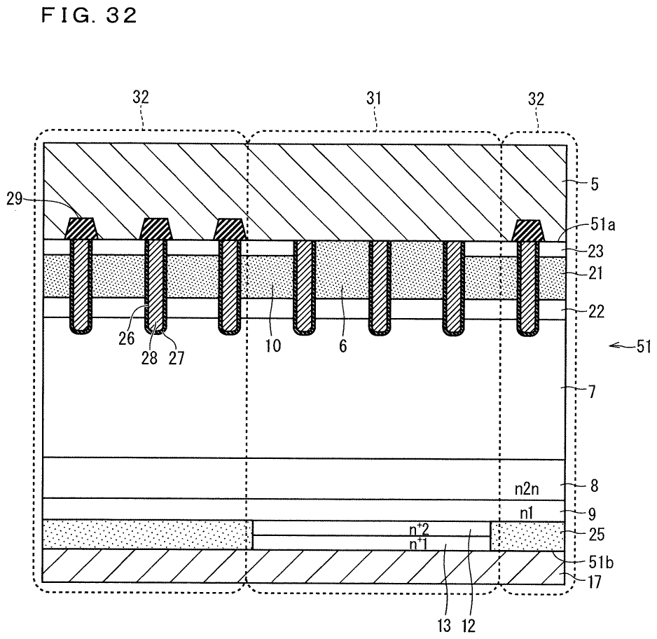

FIGS. 32 to 34 are cross-sectional views illustrating a configuration of a semiconductor device according to a fifth preferred embodiment. The semiconductor device according to the fifth preferred embodiment corresponds to an RC-IGBT in which the diodes described in the first and second preferred embodiments and the IGBT described in the fourth preferred embodiment are provided on the same semiconductor substrate 51.

In the RC-IGBT of FIG. 32, the new p-i-n diode of FIG. 2B described in the first preferred embodiment is provided in a diode region 31 of the semiconductor substrate 51, and the new IGBT of FIG. 28B described in the fourth preferred embodiment is provided in an IGBT region 32 of the semiconductor substrate 51.

That is, the diode in the diode region 31 includes the p-type anode layer 6, the n⁻-type drift layer 7, the n-type buffer layers 8 and 9, the n⁺-type cathode layer 12, which is the first semiconductor layer containing no point defects, and the n⁺-type cathode layer 13, which is the second semiconductor layer containing point defects.

The IGBT in the IGBT region 32 includes the n⁻-type drift layer 7, the n-type buffer layer 8, which is the first semiconductor layer containing point defects, the n-type buffer layer 9, which is the second semiconductor layer containing no point defects, the p-type base layer 21, the n-type layer 22, the n⁺-type emitter layer 23, the p⁺-type layer 24, which is not illustrated in FIG. 32, and the p-type collector layer 25. The p⁺-type layer 24, which is not illustrated in FIG. 32, corresponds to the p⁺-type layer 24 of FIG. 28B, and is provided in a cross section different from the cross section of FIG. 32.

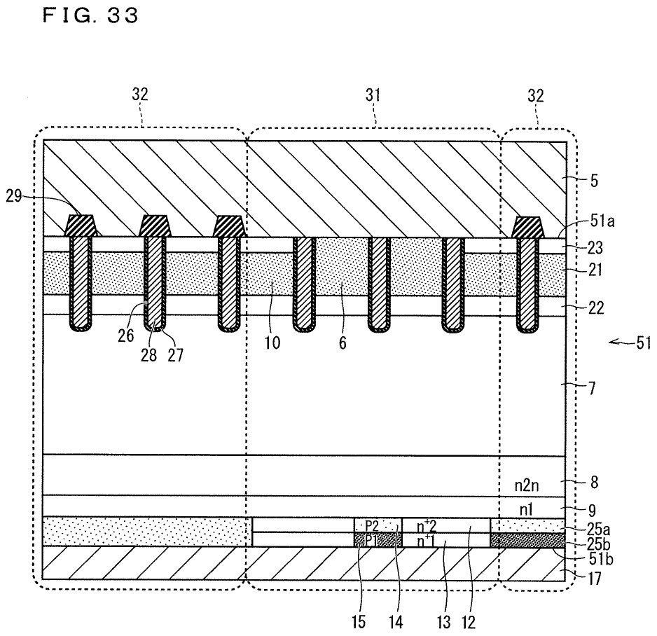

In the RC-IGBT of FIG. 33, the new diode A of FIG. 8B described in The second preferred embodiment is provided in the diode region 31 of the semiconductor substrate 51. That is, the diode in the diode region 31 includes each layer contained in the diode of FIG. 32, and the p-type cathode layers 14 and 15. Likewise, the IGBT in the IGBT region 32 of FIG. 33 includes each layer contained in the IGBT of FIG. 32, and p-type collector layers 25a and 25b similar to the p-type cathode layers 14 and 15.

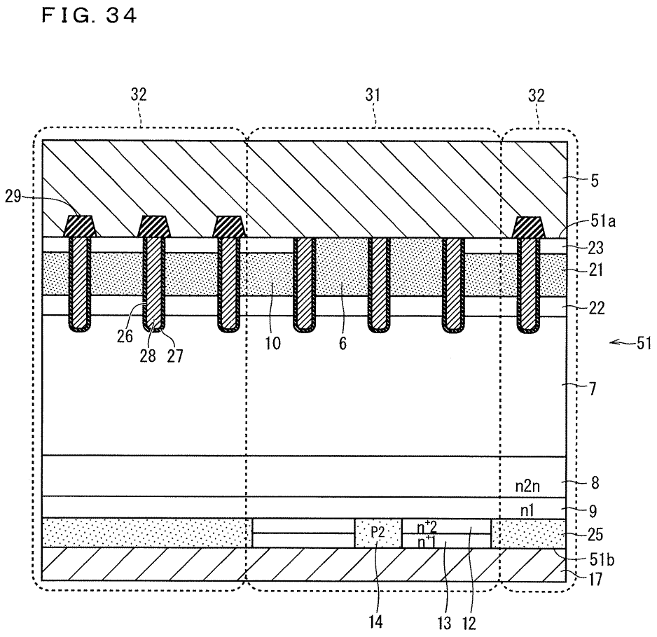

In the RC-IGBT of FIG. 34, the new diode B of FIG. 8C described in the second preferred embodiment is provided in the diode region 31 of the semiconductor substrate 51. That is, the diode in the diode region 31 includes each layer contained in the diode of FIG. 32 and the p-type cathode layer 14. Likewise, the IGBT in the IGBT region 32 of FIG. 34 includes each layer contained in the IGBT of FIG. 32.

According to the RC-IGBT of the fifth preferred embodiment, the p⁺-type layer 24 of the IGBT region 32 is not present in the diode region 31, and thus, the hole injection efficiency from the p-type base layer 21 in the ON state can be reduced.

Further, according to the RC-IGBTs of FIGS. 32 to 34, it is possible to obtain both the effects achieved by the diodes described in the first and second preferred embodiments and the effects achieved by the IGBT described in the fourth preferred embodiment. For example, the RC-IGBT of FIG. 33 has, as the cathode structure of the diode constituting the RC-IGBT, the n⁺-type cathode layers 12 and 13 and the p-type cathode layers 14 and 15. Accordingly, without performing carrier lifetime control by electron beams, it is possible to control the trade-off characteristic between the switching loss (E_{REC}) and the on-voltage (V_{F}) toward the high-speed side, while achieving lower off-state loss, improved breakdown tolerance, and enhanced stability during the continuous conduction test at a high temperature. This is particularly effective when the semiconductor substrate 51 is an MCZ wafer that is susceptible to the influence of impurities in the wafer due to carrier lifetime control by charged particles.

It should be noted that, in the RC-IGBTs of FIGS. 32 to 34 as well, the dummy trench structure described in the fourth preferred embodiment may be provided. That is, it is also possible to provide a dummy trench structure having a dummy electrode by replacing the gate electrode 28 of some gate trench structures with the dummy electrode connected to the first electrode 5 at emitter potential.

### Sixth Preferred Embodiment

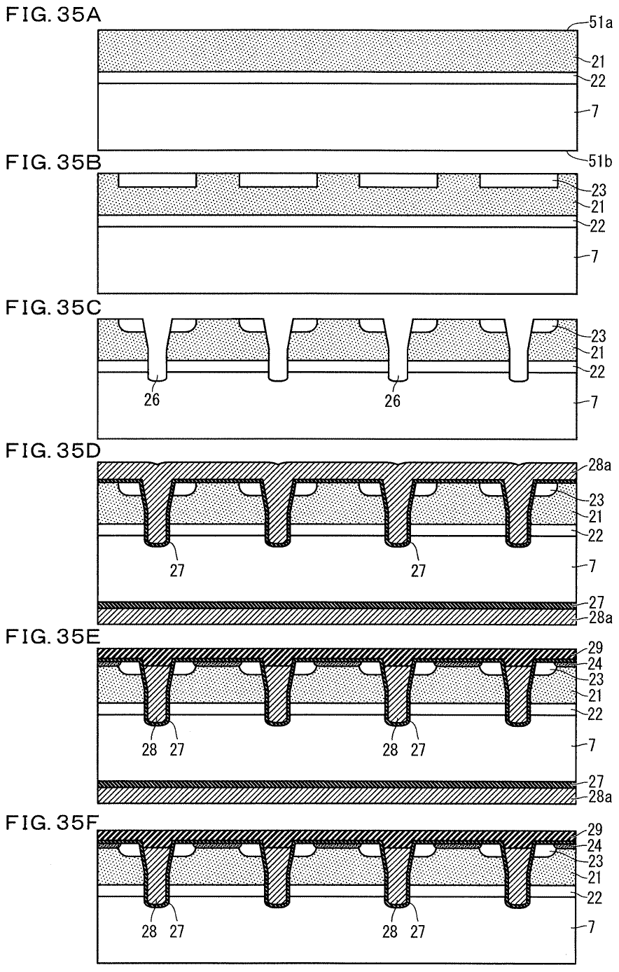

In the sixth preferred embodiment, a method of manufacturing the IGBT according to the fourth preferred embodiment will be described. FIGS. 35A to 37C are cross-sectional views illustrating steps of the manufacturing method of the sixth preferred embodiment. In the manufacturing method according to the sixth preferred embodiment, the n-type buffer layer 8 and the n-type buffer layer 9 are formed as diffusion layers in the semiconductor substrate 51, which is an MCZ wafer. In forming the n-type buffer layer 8, one or two or more kinds of different acceleration energies and dose amounts are used.

First, as illustrated in FIG. 35A, the p-type base layer 21 and the n-type layer 22 are formed on the front surface 51a side of the n⁻-type drift layer 7, which is a part of the semiconductor substrate 51, by using ion implantation and annealing. Next, as illustrated in FIG. 35B, the n⁺-type emitter layer 23 is formed on the front surface 51a side of the p-type base layer 21 by using ion implantation and annealing.

Then, as illustrated in FIG. 35C, the trench 26 penetrating through the n⁺-type emitter layer 23, the p-type base layer 21, and the n-type layer 22 is formed by etching, and cleaning, smoothing, and rounding of the inner wall of the trench 26 are performed by etching and oxidation. Next, as illustrated in FIG. 35D, the gate oxide film 27 is formed on the inner wall of the trench 26, and a polysilicon film 28a doped with an n-type element (for example, arsenic or phosphorus) at a concentration of, for example, 1×10¹⁹ atoms/cm³ or higher is formed on the gate oxide film 27. It should be noted that, in FIG. 35D, the gate oxide film 27 and the polysilicon film 28a are also formed on the back surface 51b side of the semiconductor substrate 51.

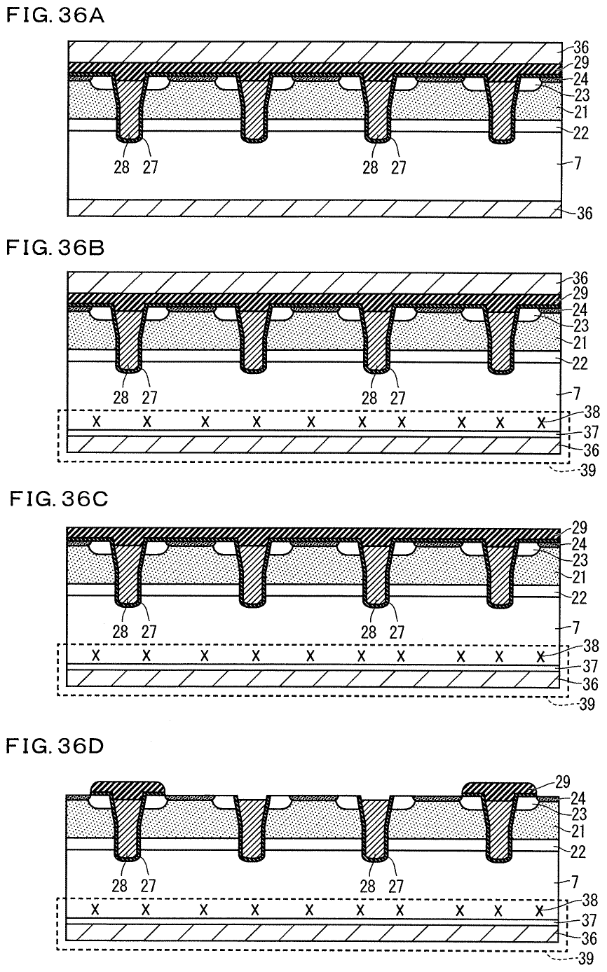

As will be described later, in the step of FIG. 36B after going through the steps of FIGS. 35E to 36A, a gettering layer 39 including a polysilicon film 36, a high-concentration n⁺-type layer 37, and a high crystal defect density layer 38 is formed on the back surface 51b side. The gettering layer 39 restores the carrier lifetime of the n⁻-type drift layer 7 so that the carrier lifetime of the n⁻-type drift layer 7 is equal to or greater than the carrier lifetime calculated by the following expression (7).

τₜ≥1.5×10⁻⁵ exp(5.4×10³×tₙ⁻) (7)

Here, tₙ₋[m] is the thickness of the n-type drift layer 7, and has a fixed relationship with t_{device} of FIG. 2A. τₜ[sec] is the carrier lifetime of the n-type drift layer 7 at which the influence of the carrier lifetime on the on-voltage of the IGBT disappears.

The on-voltage of the IGBT has dependency on the carrier lifetime of the n⁻-type drift layer 7, and expression (7) represents an index of the carrier lifetime required to minimize such dependency. When τₜ satisfies expression (7), the influence of the carrier lifetime on switching loss and turn-off loss can be suppressed, and thus a reduction in turn-off loss and suppression of thermal runaway can be expected.

Hereinafter, the steps will be described in detail in order from FIG. 35E. First, as illustrated in FIG. 35E, by removing an upper portion of the polysilicon film 28a on the front surface 51a side, the gate electrode 28 is formed, and the p⁺-type layer 24 and the interlayer film 29 are formed. Next, as illustrated in FIG. 35F, in order to expose the back surface 51b of the semiconductor substrate 51, the gate oxide film 27 and the polysilicon film 28a on the back surface 51b side are removed by wet etching using hydrofluoric acid or a mixed acid (for example, a mixture of hydrofluoric acid/nitric acid/acetic acid).

Then, as illustrated in FIG. 36A, the polysilicon film 36 doped with an n-type element is formed on the front surface 51a and the back surface 51b of the semiconductor substrate 51 by an LPCVD (low pressure CVD) method. The polysilicon film 36 is used as a source for forming the high-concentration n⁺-type layer 37 and the high crystal defect density layer 38, as illustrated in FIG. 36B. As the n-type element (atom), an element (atom) capable of diffusing into Si to form the n⁺-type layer 37, such as phosphorus, arsenic, or antimony, is used, and the element (atom) is doped into the polysilicon film 36 at, for example, a concentration of 1×10¹⁹ atoms/cm³ or more. The film thickness of the polysilicon film 36 is, for example, 500 nm or more.

Next, in a state where the back surface 51b of the semiconductor substrate 51 is in direct contact with the polysilicon film 36 doped with a high-concentration impurity such as an n-type element, annealing is performed at 900° C. to 1000° C. in a nitrogen atmosphere. Then, the temperature is lowered to 500° C. to 700° C. at any cooling rate, and annealing is performed in the nitrogen atmosphere at a temperature lower than that of the previous annealing.

As illustrated in FIG. 36B, by this annealing, the high-concentration impurity in the polysilicon film 36 diffuses into the back surface 51b of the semiconductor substrate 51 that is in direct contact with the polysilicon film 36, thereby forming the high-concentration n⁺-type layer 37. The high-concentration n⁺-type layer 37 has a surface impurity concentration of, for example, 1.0×10²⁰ atoms/cm³ to 1.0×10²² atoms/cm³, and a depth from the back surface 51b of, for example, 1.0 μm to 10 μm.

Along with the formation of the high-concentration n⁺-type layer 37, the high crystal defect density layer 38, into which high-density dislocations and lattice defects are introduced, is secondarily formed in the lower portion of the n-type drift layer 7. In addition, the above annealing is performed in a state where the polysilicon film 36 and the back surface 51b of the semiconductor substrate 51, which have different coefficients of thermal expansion, are in direct contact, and thus, strain is generated in the polysilicon film 36 and in the surface layer portion of the high-concentration n⁺-type layer 37, which is a Si junction. As a result, the gettering layer 39, i.e., a gettering site, is formed, which includes the high-concentration n⁺-type layer 37 including the Si junction, the high crystal defect density layer 38, and the polysilicon film 36. Consequently, during the annealing, heavy metals and contamination atoms which are incorporated into the semiconductor substrate 51 and diffuse in the crystal lattice are trapped at the gettering site.

By capturing the heavy metals and contaminant atoms at the gettering site, it is possible to restore the carrier lifetime of the n⁻-type drift layer 7, which has been reduced during the preceding wafer process, to the level indicated by expression (7). In other words, the carrier lifetime of the n⁻-type drift layer 7 can be made sufficiently long so that the carrier lifetime of the n⁻-type drift layer 7 does not affect the electrical characteristics, and thus the carrier lifetime, of IGBTs of various withstand voltage classes.

It should be noted that the front surface 51a of the semiconductor substrate 51 is not in direct contact with the polysilicon film 36 due to the presence of the interlayer film 29, and thus, no gettering layer 39 including the polysilicon film 36, the high-concentration n⁺-type layer 37, and the high crystal defect density layer 38 is formed on the front surface 51a side of the semiconductor substrate 51.

Instead of forming the high crystal defect density layer 38 using the polysilicon film 36, the high crystal defect density layer 38 may be formed in the semiconductor substrate 51 by performing laser annealing using a laser with a wavelength of 500 nm to 1000 nm, which enables rapid heating/rapid cooling and localized annealing. The power density of the laser annealing is, for example, 4 J/cm² or higher. After the laser annealing, annealing similar to that described above is performed. That is, annealing is performed at 900° C. to 1000° C. in a nitrogen atmosphere, followed by cooling to 500° C. to 700° C. at any cooling rate, whereupon a second annealing is performed in the nitrogen atmosphere at a temperature lower than the preceding annealing temperature. Even in this case, heavy metals and contaminant atoms incorporated into the semiconductor substrate 51 diffuse through the crystal lattice and are trapped at the gettering site, thereby restoring the carrier lifetime of the n-type drift layer 7.

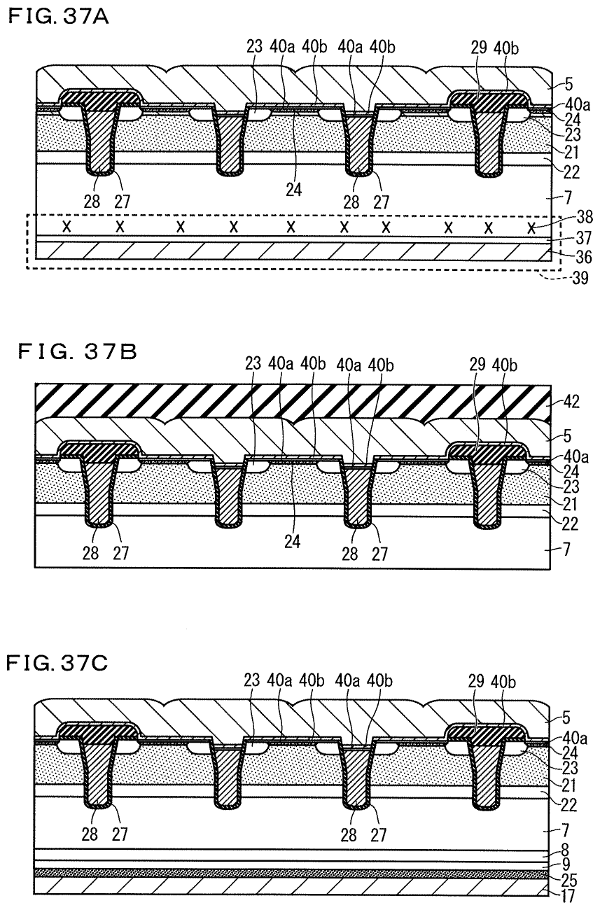

As described below, the gettering layer 39, which includes the polysilicon film 36, the high-concentration n⁺-type layer 37, and the high crystal defect density layer 38, is removed in a step of FIG. 37B, which is performed before a step of FIG. 37C for forming the n-type buffer layer 9, the n-type buffer layer 8, and the p-type collector layer 25.

As illustrated in FIG. 36C, the polysilicon film 36 on the front surface 51a side is removed by etching. Next, as illustrated in FIG. 36D, the gate oxide film 27 and the interlayer film 29 are patterned. In FIG. 36D, a part of the gate electrode 28 is exposed from the interlayer film 29; however, the gate electrode 28 may be entirely covered by the interlayer film 29.

As illustrated in FIG. 37A, a silicide layer 40a, a barrier metal layer 40b, and the first electrode 5 are sequentially formed on the front surface 51a of the semiconductor substrate 51 and on the interlayer film 29. Here, the gate electrode 28 that is exposed from the interlayer film 29 and connected to the first electrode 5 serves as a dummy electrode 41. Through the steps up to FIG. 37A, the n-type semiconductor substrate 51 is formed having the front surface 51a provided with the first electrode 5 and the back surface 51b opposite to the front surface 51a.

As illustrated in FIG. 37B, after forming a protective film 42 on the first electrode 5, the gettering layer 39 including the polysilicon film 36, the high-concentration n⁺-type layer 37, and the high crystal defect density layer 38 is removed by mechanical polishing and wet etching, thereby setting the device thickness (t_{device}) in FIG. 2A to, for example, 40 μm to 700 μm. In the step of FIG. 37B, the gettering layer 39 is removed during mechanical polishing, and crystal defects, strain layers, etc. introduced during the mechanical polishing, which cause reduction in the fracture strength of the semiconductor substrate 51, are eliminated during wet etching. As a result, both the carrier lifetime in the n⁻-type drift layer 7 and the fracture strength of the semiconductor substrate 51 are restored, and the carrier lifetime in the n⁻-type drift layer 7 satisfies the carrier lifetime of expression (7).

As illustrated in FIG. 37C, the n-type buffer layers 8 and 9, the p-type collector layer 25, and the second electrode 17 are formed on the back surface 51b, and the protective film 42 is removed. This forms a vertical structure on the back surface 51b side. On the front surface 51a, where the vertical structure is not formed, the structure of MOSFET included in the IGBT is already present, and the first electrode 5, the interlayer film 29, etc. are already present. Therefore, when forming the n-type buffer layers 8 and 9 and the p-type collector layer 25, the temperature of the first electrode 5 on the front surface 51a is kept lower than the melting point of the metal of the first electrode 5 (for example, aluminum with a melting point of 660° C.). To achieve this, a temperature gradient is established in the depth direction of the semiconductor substrate 51, and laser annealing using a laser whose wavelength renders heat transfer to the front surface 51a difficult, or annealing, etc. in a diffusion furnace at a temperature equal to or lower than the melting point of the metal, may be used.

Next, a method will be mainly described for manufacturing an IGBT, in which the n-type buffer layer 8 has n impurity concentration peaks C_{P,n21}, C_{P,n22}, . . . C_{P,n2n}, as illustrated in FIG. 20 by carrying out the steps of FIGS. 37B and 37C.

In this IGBT manufacturing method, it is important to control point defects and composite defects in the n-type buffer layer 8, and to accurately form the contact interface between the n-type buffer layer 9 and the n-type buffer layer 8 without interference between the n-type buffer layer 9 and the n-type buffer layer 8. To achieve this, as described below, the order of forming the n-type buffer layer 9 and the n-type buffer layer 8, as well as the positioning of the peak of the acceleration energy during ion implantation of the n-type buffer layer 8, are critical.

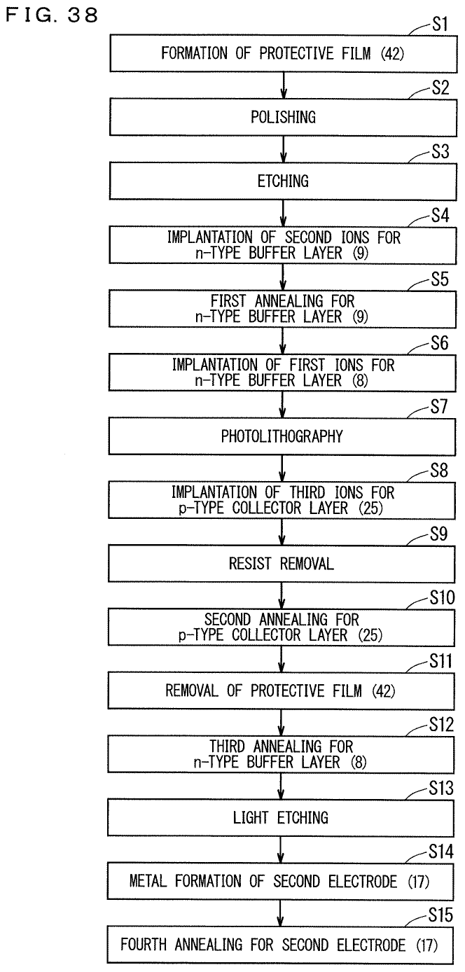

FIG. 38 is a flowchart illustrating steps of forming a structure on the back surface 51b side of the manufacturing method according to the sixth preferred embodiment, that is, a flowchart illustrating the steps of FIGS. 37B and 37C. Hereinafter, ions for forming the n-type buffer layer 8 are referred to as first ions, and ions for forming the n-type buffer layer 9 are referred to as second ions.

First, in step S1, as illustrated in FIG. 37B, the protective film 42 is formed on the first electrode 5. Through polishing in step S2 and etching in step S3, the polysilicon film 36, the high-concentration n⁺-type layer 37, and the high crystal defect density layer 38 are removed, and the device thickness (t_{device}) in FIG. 2A is adjusted, for example, to 40 μm to 700 μm.

In step S4, the second ions for the n-type buffer layer 9 are implanted to the back surface 51b side relative to the n⁻-type drift layer 7. In step S5, a first annealing of the second ions is performed, thereby forming the n-type buffer layer 9 as illustrated in FIG. 37C. The second ions contain, for example, arsenic or phosphorus.

In step S6, the first ions for the n-type buffer layer 8 are implanted between the n-type buffer layer 9 and the n⁻-type drift layer. The first ions contain protons (H⁺). It should be noted that, for proton implantation, a cyclotron may be used instead of a general ion implantation.

In step S6, the protons (the first ions) are introduced between the n-type buffer layer 9 and the n⁻-type drift layer 7 at one or more different acceleration energies and dose amounts. For example, the protons (first ions) are implanted in the order of decreasing acceleration energy, and the dose amount of the protons implanted at the first acceleration energy is made lower than the dose amount of the protons implanted at the second acceleration energy, which is lower than the first acceleration energy. Consequently, the protons are implanted in the order from the protons that form the peak C_{P,n2n} on the n⁻-type drift layer 7 side to the protons that form the peak C_{P,n21} on the n-type buffer layer 9 side among the n impurity concentration peaks of the n-type buffer layer 8, and the dose amount of the protons increases in this order. Consequently, when annealing of the protons (first ions) is performed, it is possible to form the n-type buffer layer 8 having n impurity concentration peaks C_{P,n21}, C_{P,n22}, . . . C_{P,n2n}.

Among the n impurity concentration peaks of the n-type buffer layer 8, the peak C_{P,n21} on the n-type buffer layer 9 side is set to be located closer to the junction between the n-type buffer layer 8 and the n⁻-type drift layer 7 than to the junction between the n-type buffer layer 8 and the n-type buffer layer 9. This arrangement suppresses interference between the impurities of the n-type buffer layer 9 and the peak C_{P,n21}, allowing the peak C_{P,n21} to be formed with high accuracy. The protons (first ions) may be introduced at one different acceleration energy and dose amount.

When the protons (first ions) are introduced in step S6 and a third annealing of step S12 described later is performed, the process proceeds through the following steps A21 to A24, enabling a hydrogen-induced donors (HDs) layer, in which donor-type composite defects are present, to be utilized as the n-type buffer layer 8.

First, in step A21, protons are introduced into Si, thereby generating vacancies (V) and Si interstitial pairs (I_{Si}). In step A22, at room temperature, the S1 interstitial pairs (I_{Si}) aggregate to generate W centers (I_{Si3} clusters), which are point defects. The W centers (I_{Si3} clusters) have a photon energy of 1.019 eV and are located at a level of Ev+0.1 eV in an energy band.

In step A23, through the third annealing in step S12, the Si interstitial pairs (I_{Si}) re-aggregate, generating X centers (I_{Si4} clusters), which are point defects. The X centers (I_{Si4} clusters) have a photon energy of 1.040 eV and are located at a level of Ev+0.32 eV in the energy band. In step A24, the hydrogen introduced by the protons reacts with the W centers (I_{Si3} clusters) and the X centers (I_{Si4} clusters) to form the HDs layer.

As described above, if annealing of the protons (first ions) is performed after step S6, the n-type buffer layer 8 can be formed. It is assumed that the first annealing in step S5 for forming the n-type buffer layer 9 is performed at a higher temperature than the third annealing for activating and forming the n-type buffer layer 8. Therefore, when the first annealing is performed at a temperature higher than that of the third annealing after the third annealing, an adverse effect is exerted on the impurity profile of the HDs layer and on the point defects and composite defects in the n-type buffer layer 8 which are introduced for forming the n-type buffer layer 8. Consequently, it is considered that an adverse effect is exerted on the carriers (electrons or holes) which are present when the IGBT is in the ON state. Accordingly, in the sixth preferred embodiment, the third annealing (step S12) for forming the n-type buffer layer 8 is performed after the first annealing (step S5) for forming the n-type buffer layer 9.

When an FZ wafer is used for the semiconductor substrate 51, the HDs layer itself serves as the n-type buffer layer 8. On the other hand, when an MCZ wafer is used for the semiconductor substrate 51 to form the HDs layer, the thermal donorization phenomenon caused by oxygen in Si is additionally involved, thereby ultimately forming the n-type buffer layer 8. For example, in the n-type buffer layer 8, particularly in the portion on the n⁻-type drift layer side that is formed with a low dose amount, the impurity profile may broaden due to the thermal donorization phenomenon caused by oxygen in Si. Here, broadening of the profile means that the impurity concentration is substantially constant between adjacent peaks.

In the sixth preferred embodiment, an MCZ wafer is used for the semiconductor substrate 51, and thus, thermal donorization due to the oxygen concentration [Oᵢ] in Si may cause broadening of the profile of the n-type buffer layer 8. In this case, an n-layer donorized at a higher impurity concentration than the n′-type drift layer 7 can contribute to device operation as the n-type buffer layer 8. Furthermore, composite defects formed in the n-type buffer layer 8 can be utilized to enhance the device performance.

It should be noted that among the composite defects formed in the n-type buffer layer 8, there are also defects that act as lifetime killers, which reduce the carrier lifetime. Therefore, in the sixth preferred embodiment, the following steps are performed in this order: a step (step S4) of implanting the second ions, a first annealing step (step S5) of annealing the second ions to form the n-type buffer layer 9, a step (step S6) of implanting the first ions, and a third annealing step (step S12) of annealing the first ions to form the n-type buffer layer 8. According to such a manufacturing method, it is possible to control the composite defects in the n-type buffer layer 8, thereby enabling both the removal of defects that act as lifetime killers and the stabilization of the profile of the n-type buffer layer 8.

In step S7, photolithography is performed to form a patterned resist on the back surface 51b as a mask. In step S8, third ions for the p-type collector layer 25 are implanted on the back surface 51b side of the n-type buffer layer 9 that is exposed from the mask. The third ions contain, for example, boron. In step S9, the resist is removed. When there is no need to partially form the p-type collector layer 25, steps S7 and S9 may be omitted. In step S10, the second annealing of boron (third ions) is performed to form the p-type collector layer 25. When, for example, the same annealing as in the first annealing step is performed in the second annealing, the step of implanting the first ions as step S6 may be performed in step S10 instead. In step S11, the protective film 42 on the first electrode 5 is removed.

In step S12, the third annealing of the protons (first ions) is performed to form the n-type buffer layer 8. As the third annealing for donorization of the n-type buffer layer 8, the protons (first ions) are annealed at a temperature in a range of 375° C. to 425° C., inclusive, for a duration of 90 minutes or longer. In the third annealing, annealing different from that in the first annealing step is performed. Through step S12, the carrier lifetime of the n⁻-type drift layer 7, the n-type buffer layer 9, and the n-type buffer layer 8 may satisfy the following expression (8).

τ₂<τ₁≤τₜ (8)

Here, τ₂ is the carrier lifetime of the n-type buffer layer 8, τ₁ is the carrier lifetime of the n-type buffer layer 9, and τₜ is the carrier lifetime of the n⁻-type drift layer 7 at which there is no influence on the on-voltage of the IGBT.

In step S13, a light etching is performed on the back surface 51b of the semiconductor substrate 51. In step S14, a metal film serving as the second electrode 17 is formed on the back surface 51b of the semiconductor substrate 51 by sputtering. The metal film is, for example, an Al—Si film in which the Si content is 1% to 3%. In step S15, a fourth annealing is performed to form an alloy layer or silicide layer between the back surface 51b of the semiconductor substrate 51 and the metal film, thereby forming the second electrode 17. The temperature of the fourth annealing is, for example, lower than that of the third annealing, and is, for example, below 375° C.

According to the method of manufacturing the semiconductor device of the sixth preferred embodiment described above, it is possible to complete the IGBT of the fourth preferred embodiment. In the completed IGBT, when the maximum oxygen concentration in the semiconductor substrate 51 is defined as maximum [Oᵢ], expression (1) is satisfied, and the n-type buffer layer 8 containing point defects and the n-type buffer layer 9 containing no point defects are formed. Furthermore, according to this manufacturing method, it is possible to form, in an MCZ wafer having a high oxygen concentration and containing antimony as an n-type dopant, the n-type buffer layer 8, which includes the HDs layer and is also subjected to the thermal donorization phenomenon, by the third annealing of the protons (first ions).

### Seventh Preferred Embodiment

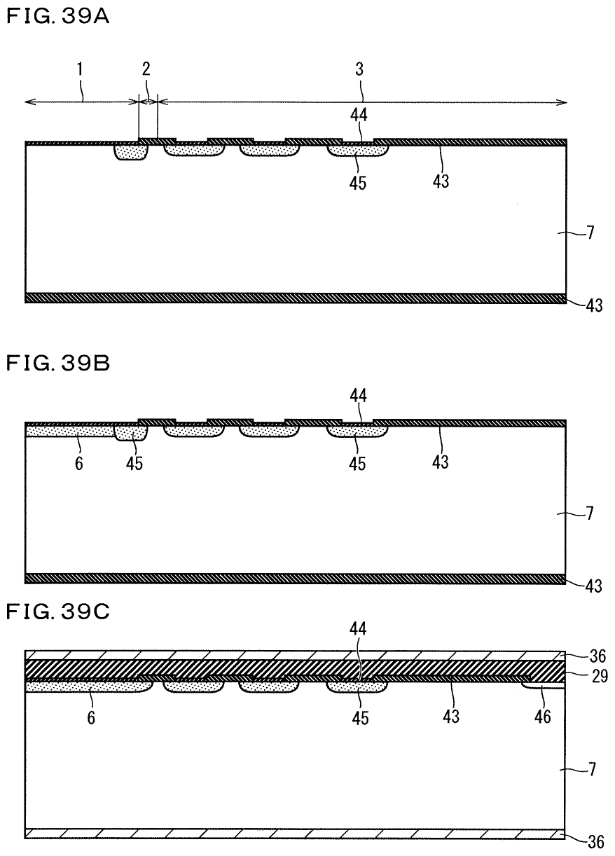

In the seventh preferred embodiment, the method of manufacturing the diodes according to the first and second preferred embodiments (the new p-i-n diode of FIG. 2B and the new diode A of FIG. 8B) will be described. FIGS. 39A to 41C are cross-sectional views illustrating the steps of the manufacturing method of the seventh preferred embodiment, specifically, cross-sectional views illustrating the steps of the method of manufacturing the new diode A of FIG. 8B. In the seventh preferred embodiment, similarly to the sixth preferred embodiment, the n-type buffer layers 8 and 9 are formed in the semiconductor substrate 51 including the MCZ wafer, and the formation of the n-type buffer layer 8 uses one or two or more kinds of different acceleration energies and dose amounts.

First, as illustrated in FIG. 39A, a patterned oxide film 43 is formed on the front surface 51a of the semiconductor substrate 51 by performing photolithography and resist removal. Thereafter, a thin oxide film 44 is formed by re-oxidation, and using ion implantation, photolithography, resist removal, and annealing, a p-type layer 45 is formed on the front surface 51a side of the n-type drift layer 7 in the termination region 3. Next, as illustrated in FIG. 39B, using ion implantation, photolithography, resist removal, and annealing, the p-type anode layer 6 is formed on the front surface 51a side of the n-type drift layer 7 in the active region 1. Then, as illustrated in FIG. 39C, a portion of the oxide film 43 in the termination region 3 is removed, and using ion implantation, photolithography, resist removal, and annealing, an n⁺-type layer 46 is formed on the front surface 51a. Thereafter, the oxide-based interlayer film 29 is formed on the front surface 51a, and then, on both the front surface 51a side and the back surface 51b side, the polysilicon film 36 described in the sixth preferred embodiment is formed.

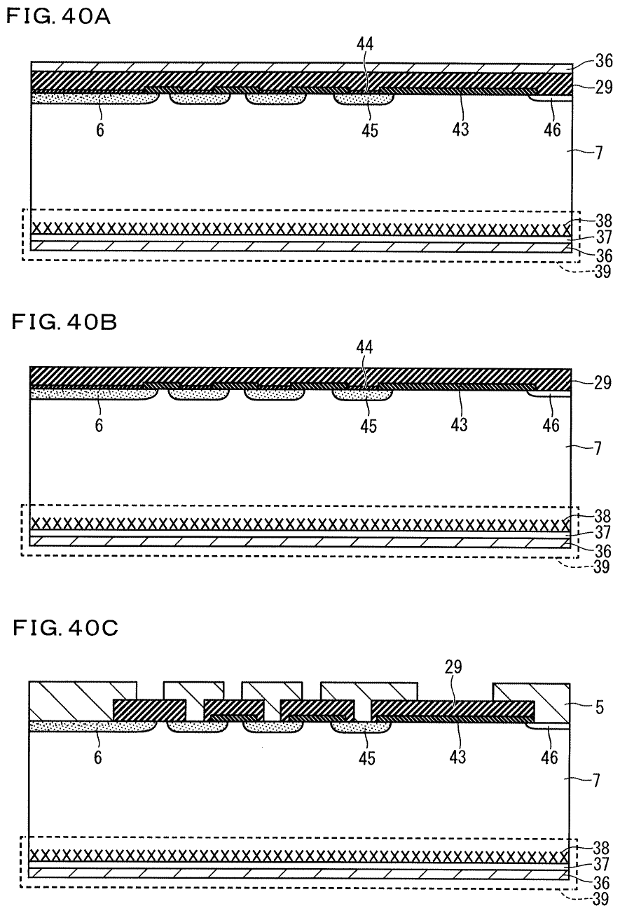

Then, annealing is performed at 900° C. to 1000° C. in a nitrogen atmosphere, followed by cooling to 500° C. to 700° C. at any cooling rate, whereupon a annealing is performed in the nitrogen atmosphere at a temperature lower than the preceding annealing temperature. Thus, as illustrated in FIG. 40A, the gettering layer 39 (gettering site) including the polysilicon film 36, the high-concentration n⁺-type layer 37, and the high crystal defect density layer 38 is formed on the back surface 51b side. As a result, even in the n⁻-type drift layer 7 according to the seventh preferred embodiment, the carrier lifetime is restored in a similar manner as in the n⁻-type drift layer 7 according to the sixth preferred embodiment, and expression (7) is satisfied.

Then, as illustrated in FIG. 40B, the polysilicon film 36 on the front surface 51a side is removed by etching. Next, as illustrated in FIG. 40C, the interlayer film 29 and the thin oxide film 44 are patterned, and the first electrode 5 is formed on the exposed p-type anode layer 6, the p-type layer 45, and the n⁺-type layer 46, as well as on the interlayer film 29. As in FIG. 37A, a silicide layer 40a and a barrier metal layer 40b may be provided.

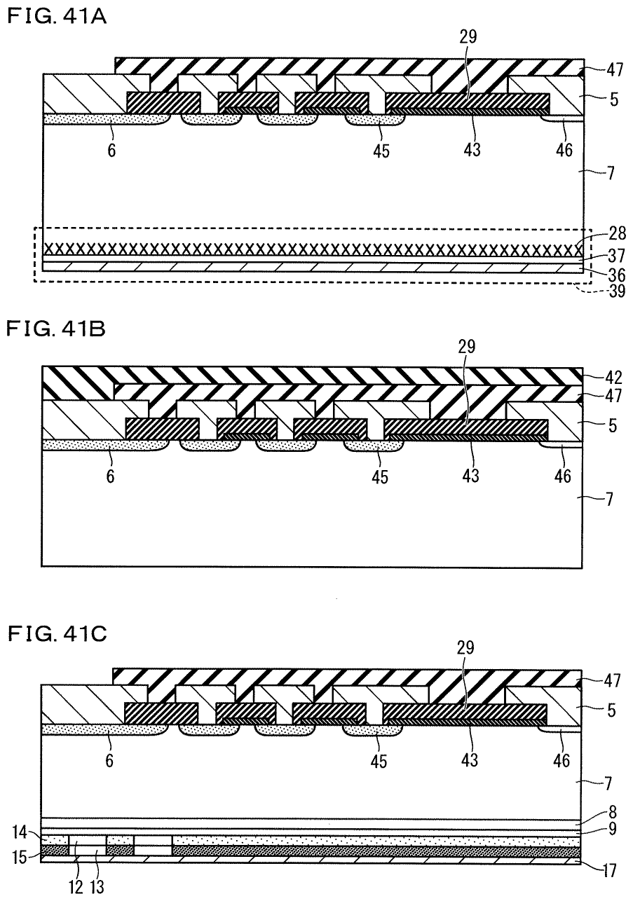

Next, as illustrated in FIG. 41A, a passivation film 47 is selectively formed on the first electrode 5. Then, as illustrated in FIG. 41B, the protective film 42 is formed on the first electrode 5, the passivation film 47, etc. Thereafter, the polysilicon film 36, the high-concentration n⁺-type layer 37, and the high crystal defect density layer 38 are removed by polishing and wet etching, thereby adjusting the device thickness (t_{device}) to, for example, 40 μm to 700 μm. In the step of FIG. 41B, crystal defects, strain layers, etc., which cause deterioration in the carrier lifetime in the n-type drift layer 7 and reduction in the fracture strength of the semiconductor substrate 51, are removed during mechanical polishing. Consequently, the carrier lifetime in the n⁻-type drift layer 7 and the fracture strength of the semiconductor substrate 51 are restored, and the carrier lifetime in the n⁻-type drift layer 7 is restored to the carrier lifetime of expression (7).

Then, as illustrated in FIG. 41C, the n-type buffer layers 8 and 9, the n⁺-type cathode layers 12 and 13, and the p-type cathode layers 14 and 15 are formed on the back surface 51b, and the protective film 42 is removed.

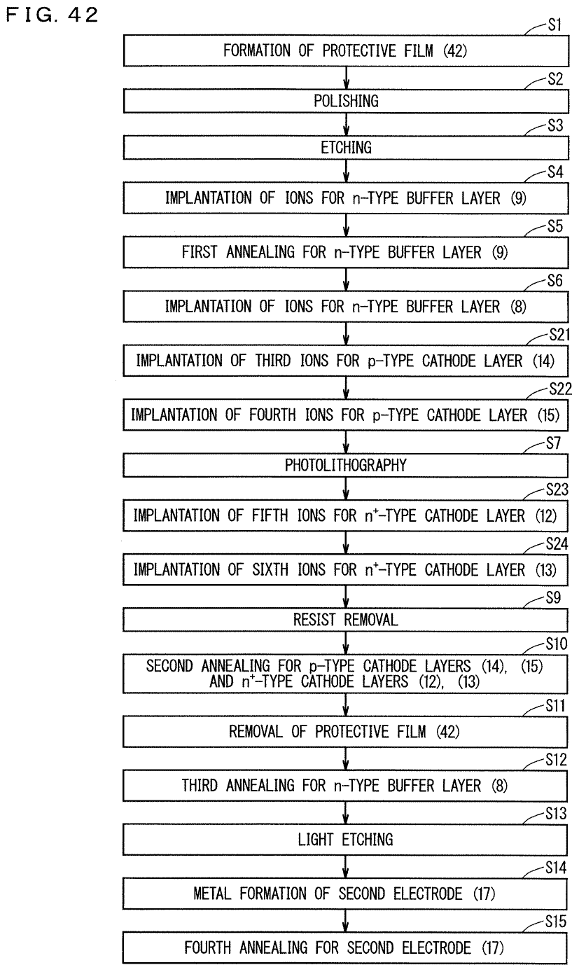

FIG. 42 is a flowchart illustrating the steps of FIGS. 41B and 41C among the steps of forming the structure on the back surface 51b side in the manufacturing method according to the seventh preferred embodiment for the new diode A of FIG. 8B. The steps of FIG. 42 are similar to the steps of FIG. 38, except that steps S21 and S22 are added between steps S6 and S7, and step S8 is replaced with steps S23 and S24. Hereinafter, ions for forming the n⁺-type cathode layer 12 are referred to as first ions, and ions for forming the n⁺-type cathode layer 13 are referred to as second ions. In addition, ions for forming the p-type cathode layer 14 are referred to as third ions, and ions for forming the p-type cathode layer 15 are referred to as fourth ions.

In step S21, into the back surface 51b side of the n-type buffer layer 9, the third ions containing, for example, boron for the p-type cathode layer 14 are implanted. In step S22, on the back surface 51b side of the portion into which the third ions have been implanted, the fourth ions containing, for example, boron for the p-type cathode layer 15 are implanted at an impurity concentration different from that of the third ions.

In step S23, performed after step S7, fifth ions containing, for example, arsenic or phosphorus for the n⁺-type cathode layer 12 are selectively implanted into the portions where the third ions and the fourth ions have been implanted, at an impurity concentration higher than those of the third ions and the fourth ions. In step S24, on the back surface 51b side of the portion into which the fifth ions have been implanted, sixth ions containing, for example, arsenic or phosphorus for the n⁺-type cathode layer 13 are implanted at an impurity concentration higher than those of the third and fourth ions and different from that of the fifth ions.

In step S10 performed after steps S24 and S9, the fifth ions, the sixth ions, the third ions, and the fourth ions are annealed in parallel as a second annealing step, thereby forming the n⁺-type cathode layers 12 and 13 and the p-type cathode layers 14 and 15. Through the steps of FIGS. 39A to 42 described above, the new diode A of FIG. 8B satisfying expressions (7) and (8) is formed.

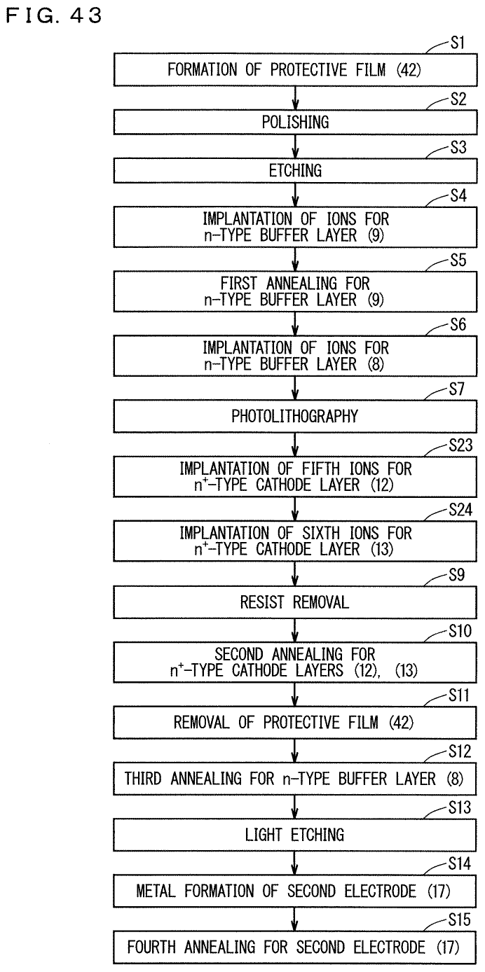

FIG. 43 is a flowchart illustrating a step of forming the structure on the back surface 51b side in the manufacturing method according to the seventh preferred embodiment for the new p-i-n diode of FIG. 2B. The steps of FIG. 43 are similar to the steps of FIG. 42, except that steps S21 and S22 are omitted. In step S10, when the second annealing is performed, the n⁺-type cathode layers 12 and 13 are formed without forming the p-type cathode layers 14 and 15. It should be noted that when it is unnecessary to partially form the n⁺-type cathode layers 12 and 13, steps S7 and S9 may be omitted.

Although not illustrated, in the manufacturing method of the new diode B of FIG. 8C, the steps are similar to the steps of FIG. 42 except that step S22 of implanting the fourth ions (ions for the p-type cathode layer 15) is omitted.

According to the method of manufacturing the semiconductor device of the seventh preferred embodiment described above, the diodes according to the first and second preferred embodiments can be completed. In the completed diodes, when the maximum oxygen concentration in the semiconductor substrate 51 is defined as maximum [Oᵢ], expression (1) is satisfied, and the n⁺-type cathode layer 13 containing point defects and the n⁺-type cathode layer 12 containing no point defects are formed. Furthermore, according to this manufacturing method, it is possible to form, in an MCZ wafer having a high oxygen concentration and containing antimony as an n-type dopant, the n-type buffer layer 8, which includes the HDs layer and is also subjected to the thermal donorization phenomenon, by the third annealing of the protons (first ions).

### Eighth Preferred Embodiment

The annealing step (the third annealing step) of the n-type buffer layer 8 in the sixth and seventh preferred embodiments is described below.

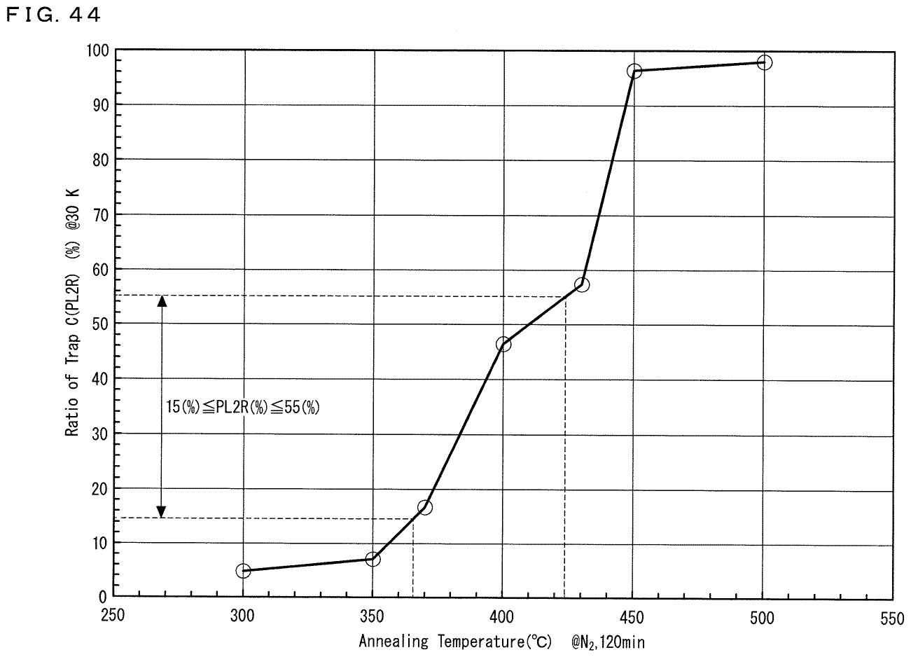

FIG. 44 is a graph illustrating a relationship between the PL2R ratio of the PL intensity of trap C among the point defects in the n-type buffer layer 8 and the annealing temperature in the annealing step (the third annealing step) of the n-type buffer layer 8. Here, the annealing time is 120 minutes. FIG. 44 indicates that, in order to control the PL2R ratio (%) of the PL intensity of trap C to be in the range of 15(%) to 55(%), inclusive, it is preferable that the annealing temperature for forming the n-type buffer layer 8 is in the range of 375° C. to 425° C., inclusive. When the annealing temperature is in the range of 375° C. to 425° C., inclusive, the carrier lifetime in the n-type drift layer 7 is restored to the carrier lifetime of expression (7).

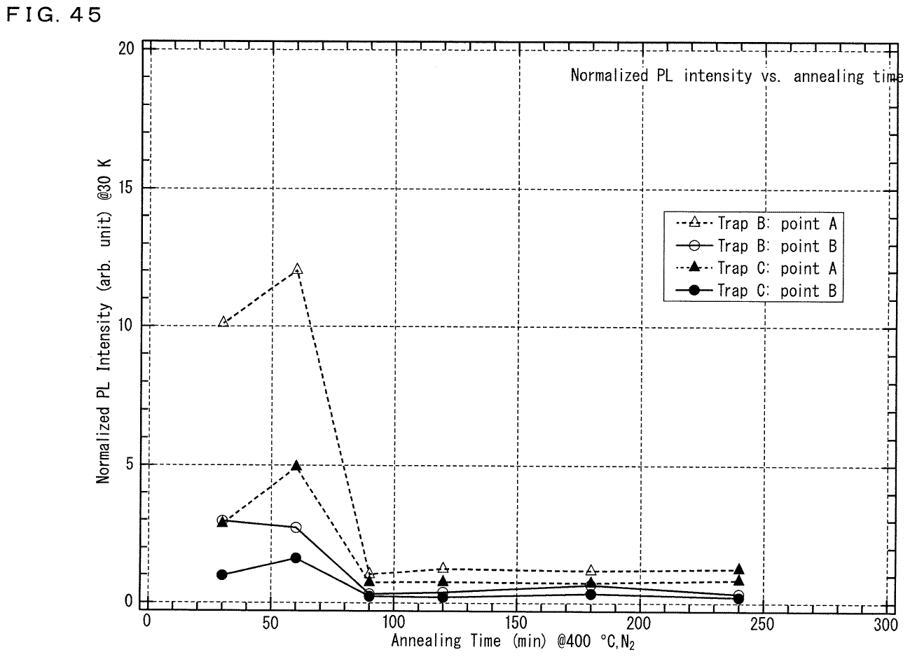

FIG. 45 is a graph illustrating a relationship between the PL intensities of traps B and C, analyzed by the PL method, and the annealing time in the annealing step (the third annealing step) of the n-type buffer layer 8, with the PL2R ratio (%) of the PL intensity of trap C in the n-type buffer layer 8 being controlled to be in the range of 15(%) to 55(%), inclusive. The annealing temperature is 400° C. Points A and B in FIG. 45 correspond to the points A and B in FIG. 22.

When the PL2R ratio (%) is controlled to be in the range of 15(%) to 55(%), inclusive, the defect densities of traps B and C may be reduced from the standpoint of the FWD performance of the IGBT in order to satisfy expression (7). As illustrated in FIG. 45, when the annealing time is 90 minutes or longer, the PL intensities representing the defect densities of traps B and C can be reduced, and the annealing time dependency of the PL intensities can be made less sensitive. Therefore, when the PL2R ratio (%) is controlled to be in the range of 15(%) to 55(%), inclusive, it is preferable to set the annealing time to 90 minutes or longer to reduce the defect densities of traps B and C.

According to the eighth preferred embodiment described above, the PL2R ratio (%) of the PL intensity of trap C can be controlled to be in the range of 15(%) to 55(%), inclusive, and the PL intensities representing the defect densities of traps B and C can be reduced.

It should be noted that, in the present disclosure in English, the articles “a” and “an” mean “one or more”. Accordingly, “a”, “an”, “one or more” and “at least one” may be used interchangeably.

Note that each of the preferred embodiments and modifications can be freely combined and each of the preferred embodiments and modifications can be modified or omitted as appropriate.

Aspects of the present disclosure are collectively described below as appendices.
(Appendix 1)

A semiconductor device comprising:
a semiconductor substrate that has a first main surface and a second main surface opposite to the first main surface; and
a first electrode and a second electrode that are respectively provided on the first main surface and the second main surface,
wherein the semiconductor substrate includes:
a drift layer of a first conductivity type which is provided between the first main surface and the second main surface, and
a first semiconductor layer and a second semiconductor layer that are provided between the drift layer and the second electrode, each having a peak impurity concentration of the first conductivity type,
the second semiconductor layer is provided on the second electrode side of the first semiconductor layer,
one of the first semiconductor layer and the second semiconductor layer contains point defects while another of the first semiconductor layer and the second semiconductor layer does not contain the point defects, and
when a maximum oxygen concentration in the semiconductor substrate calculated using a conversion coefficient of ASTM F121-79 (Old ASTM) is defined as maximum [Oᵢ] and an impurity concentration of the first conductivity type in the drift layer is defined as C_{drift}, a relationship of

maximum [Oᵢ]=9.40×10¹⁶×ln(C_{drift})−2.27×10¹⁸
is satisfied.
(Appendix 2)

The semiconductor device according to Appendix 1, wherein
the first semiconductor layer does not contain the point defects,
the second semiconductor layer is connected to the second electrode and contains the point defects, and
photon energy of the point defects, whose intensity peak is detected by a photoluminescence method, includes at least one of 0.969 eV and 1.018 eV.
(Appendix 3)

The semiconductor device according to Appendix 2, wherein the photon energy of the point defects includes 1.018 eV.
(Appendix 4)

The semiconductor device according to any one of Appendices 1 to 3, wherein when dose amounts of the first semiconductor layer and the second semiconductor layer are Dₙ₊₂ and Dₙ₊₁, respectively, a relationship of

Dₙ₊₁≥0.3×Dⁿ⁺²
is satisfied.
(Appendix 5)

The semiconductor device according to any one of Appendices 1 to 4, wherein
the semiconductor substrate further includes a third semiconductor layer of a second conductivity type which is adjacent to the first semiconductor layer and the second semiconductor layer and is provided between the drift layer and the second electrode, and
when dose amounts of the first semiconductor layer and the third semiconductor layer are Dₙ₊₂ and Dₚ₂, respectively, a relationship of

Dₙ₊₂≥2.0×Dₚ₂
is satisfied.
(Appendix 6)

The semiconductor device according to Appendix 1, wherein
the first semiconductor layer contains the point defects,
the second semiconductor layer does not contain the point defects, and
photon energy of the point defects, whose intensity peak is detected by a photoluminescence method, includes 1.018 eV and 1.040 eV.
(Appendix 7)

The semiconductor device according to Appendix 6, wherein
when the intensity peak having the photon energy of 1.018 eV is defined as PL1 and the intensity peak having the photon energy of 1.040 eV is defined as PL2, a relationship of

PL2R=PL2/(PL1+PL2)×100 and 15≤PL2R≤55
is satisfied.
(Appendix 8)

The semiconductor device according to any one of Appendices 1 to 7, wherein
the drift layer contains antimony as an impurity of the first conductivity type.
(Appendix 9)

The semiconductor device according to Appendix 1, wherein
the first semiconductor layer contains the point defects and contains protons as an impurity of the first conductivity type, and
the second semiconductor layer does not contain the point defects and contains phosphorus or arsenic as an impurity of the first conductivity type.
(Appendix 10)

The semiconductor device according to Appendix 1, wherein
the semiconductor substrate further includes an anode layer of a second conductivity type which is provided between the first electrode and the drift layer,
the first semiconductor layer does not contain the point defects, and
the second semiconductor layer is connected to the second electrode and contains the point defects.
(Appendix 11)

The semiconductor device according to Appendix 10, wherein
the semiconductor substrate further includes a third semiconductor layer and a fourth semiconductor layer each having a peak impurity concentration of the second conductivity type which are adjacent to the first semiconductor layer and the second semiconductor layer and are provided between the drift layer and the second electrode, and
the fourth semiconductor layer is provided on the second electrode side of the third semiconductor layer.
(Appendix 12)

The semiconductor device according to Appendix 10, wherein
the semiconductor substrate further includes a third semiconductor layer having a peak impurity concentration of the second conductivity type which is adjacent to the first semiconductor layer and the second semiconductor layer and is provided between the drift layer and the second electrode.
(Appendix 13)

The semiconductor device according to Appendix 1, wherein
the semiconductor substrate further includes
a base layer of a second conductivity type which is provided between the first electrode and the drift layer,
an emitter layer of the first conductivity type which is provided between the first electrode and the base layer, and
a third semiconductor layer of the second conductivity type which is provided on the second electrode side of the second semiconductor layer and is connected to the second electrode, and
the semiconductor device further comprises a gate electrode that is provided in a trench penetrating the emitter layer and the base layer via a gate insulating film.
(Appendix 14)

The semiconductor device according to Appendix 1, further comprising:
a diode and an IGBT that are provided in the semiconductor substrate,
wherein in the diode, the semiconductor substrate includes
an anode layer of a second conductivity type which is provided between the first electrode and the drift layer,
the first semiconductor layer which does not contain the point defects, and
the second semiconductor layer which contains the point defects, and
in the IGBT, the semiconductor substrate includes
a base layer of the second conductivity type which is provided between the first electrode and the drift layer,
an emitter layer of the first conductivity type which is provided between the first electrode and the base layer,
the first semiconductor layer which contains the point defects, and the second semiconductor layer which does not contain the point defects, and
the semiconductor device further comprises a gate electrode that is provided in a trench penetrating the emitter layer and the base layer via a gate insulating film.
(Appendix 15)

The semiconductor device according to Appendix 14, wherein
the semiconductor substrate further includes a third semiconductor layer and a fourth semiconductor layer each having a peak impurity concentration of the second conductivity type which are adjacent to the first semiconductor layer and the second semiconductor layer and are provided between the drift layer and the second electrode,
the fourth semiconductor layer is provided on the second electrode side of the third semiconductor layer, and
the diode further includes the third semiconductor layer and the fourth semiconductor layer.
(Appendix 16)

The semiconductor device according to Appendix 14, wherein
the semiconductor substrate further includes a third semiconductor layer having a peak impurity concentration of the second conductivity type which is adjacent to the first semiconductor layer and the second semiconductor layer and is provided between the drift layer and the second electrode, and
the diode further includes the third semiconductor layer.
(Appendix 17)

The semiconductor device according to Appendix 13, wherein
the semiconductor device is an IGBT, and
the IGBT includes a dummy trench structure having a dummy electrode electrically connected to the first electrode.
(Appendix 18)

The semiconductor device according to Appendix 14, wherein
the IGBT includes a dummy trench structure having a dummy electrode electrically connected to the first electrode.
(Appendix 19)

The semiconductor device according to Appendix 15, wherein
the IGBT includes a dummy trench structure having a dummy electrode electrically connected to the first electrode.
(Appendix 20)

The semiconductor device according to Appendix 16, wherein
the IGBT includes a dummy trench structure having a dummy electrode electrically connected to the first electrode.
(Appendix 21)

A method of manufacturing a semiconductor device, the method comprising:
a step of preparing a semiconductor substrate of a first conductivity type having a first main surface provided with a first electrode and a second main surface opposite to the first main surface;
a step of implanting first ions into a portion of the semiconductor substrate on a side closer to the second main surface than a drift layer;
a step of implanting second ions into the semiconductor substrate on a side closer to the second main surface than the portion into which the first ions have been implanted;
a step of forming a first semiconductor layer of the first conductivity type by annealing the first ions;
a step of forming a second semiconductor layer of the first conductivity type by annealing the second ions; and
a step of forming a second electrode on the second main surface,
wherein one of the first semiconductor layer and the second semiconductor layer contains point defects while another of the first semiconductor layer and the second semiconductor layer does not contain the point defects, and
when a maximum oxygen concentration in the semiconductor substrate calculated using a conversion coefficient of ASTM F121-79 (Old ASTM) is defined as maximum [Oᵢ] and an impurity concentration of the first conductivity type in the drift layer is defined as C_{drift}, a relationship of

maximum [Oᵢ]=9.40×10¹⁶×ln(C_{drift})−2.27×10¹⁸
is satisfied.
(Appendix 22)

The method according to Appendix 21, wherein
the step of implanting the second ions, the step of annealing the second ions, the step of implanting the first ions, and the step of annealing the first ions are performed in this order.
(Appendix 23)

The method according to Appendix 21 or 22, further comprising:
a step of implanting third ions into a portion of the semiconductor substrate on a side closer to the second main surface than the drift layer;
a step of implanting fourth ions into another portion of the semiconductor substrate on a side closer to the second main surface than the portion into which the third ions have been implanted;
a step of forming a third semiconductor layer of a second conductivity type by annealing the third ions; and
a step of forming a fourth semiconductor layer of the second conductivity type by annealing the fourth ions,
wherein after performing a step of implanting fifth ions, a step of implanting sixth ions, the step of implanting the third ions, and the step of implanting the fourth ions, a step of annealing the fifth ions, a step of annealing the sixth ions, the step of annealing the third ions, and the step of annealing the fourth ions are performed in parallel.
(Appendix 24)

The method according to Appendix 21 or 22, wherein
after performing a step of implanting fifth ions and a step of implanting sixth ions, a step of annealing the fifth ions and a step of annealing the sixth ions are performed in parallel.
(Appendix 25)

The method according to any one of Appendices 21 to 24, wherein
the first ions are implanted in an order of decreasing acceleration energy, and
a dose amount of the first ions implanted at a first acceleration energy is lower than a dose amount of the first ions implanted at a second acceleration energy lower than the first acceleration energy.
(Appendix 26)

The method according to any one of Appendices 21 to 25, wherein
the first ions contain protons, and
the second ions contain arsenic or phosphorus.
(Appendix 27)

The method according to Appendix 21, wherein
the first ions are annealed at a temperature in a range of 375° C. to 425° C., inclusive, for a duration of 90 minutes or longer.
(Appendix 28)

The method according to any one of Appendices 21 to 27, wherein
the semiconductor substrate includes a semiconductor wafer produced by a MCZ method.
(Appendix 29)

The method according to any one of Appendices 21 to 28, wherein
the semiconductor substrate contains antimony as an impurity of the first conductivity type.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate that has a first main surface and a second main surface opposite to the first main surface; and
a first electrode and a second electrode that are respectively provided on the first main surface and the second main surface,
wherein the semiconductor substrate includes:
a drift layer of a first conductivity type which is provided between the first main surface and the second main surface, and
a first semiconductor layer and a second semiconductor layer that are provided between the drift layer and the second electrode, each having a peak impurity concentration of the first conductivity type,
the second semiconductor layer is provided on the second electrode side of the first semiconductor layer,
one of the first semiconductor layer and the second semiconductor layer contains point defects while another of the first semiconductor layer and the second semiconductor layer does not contain the point defects, and
when a maximum oxygen concentration in the semiconductor substrate calculated using a conversion coefficient of ASTM F121-79 (Old ASTM) is defined as maximum [Oᵢ] and an impurity concentration of the first conductivity type in the drift layer is defined as C_{drift}, a relationship of
maximum [Oᵢ]=9.40×10¹⁶×ln(C_{drift})−2.27×10¹⁸
is satisfied.

2. The semiconductor device according to claim 1, wherein
the first semiconductor layer does not contain the point defects,
the second semiconductor layer is connected to the second electrode and contains the point defects, and
photon energy of the point defects, whose intensity peak is detected by a photoluminescence method, includes at least one of 0.969 eV and 1.018 eV.

3. The semiconductor device according to claim 2, wherein
the photon energy of the point defects includes 1.018 eV.

4. The semiconductor device according to claim 1, wherein
when dose amounts of the first semiconductor layer and the second semiconductor layer are Dₙ₊₂ and Dₙ₊₁, respectively, a relationship of
Dₙ₊₁≥0.3×Dₙ₊₂
is satisfied.

5. The semiconductor device according to claim 1, wherein
the semiconductor substrate further includes a third semiconductor layer of a second conductivity type which is adjacent to the first semiconductor layer and the second semiconductor layer and is provided between the drift layer and the second electrode, and
when dose amounts of the first semiconductor layer and the third semiconductor layer are Dₙ₊₂ and Dₚ₂, respectively, a relationship of
Dₙ₊₂≥2.0×Dₚ₂
is satisfied.

6. The semiconductor device according to claim 1, wherein
the first semiconductor layer contains the point defects,
the second semiconductor layer does not contain the point defects, and
photon energy of the point defects, whose intensity peak is detected by a photoluminescence method, includes 1.018 eV and 1.040 eV.

7. The semiconductor device according to claim 6, wherein,
when the intensity peak having the photon energy of 1.018 eV is defined as PL1 and the intensity peak having the photon energy of 1.040 eV is defined as PL2, a relationship of
PL2R=PL2/(PL1+PL2)×100 and 15≤PL2R≤55
is satisfied.

8. The semiconductor device according to claim 1, wherein
the drift layer contains antimony as an impurity of the first conductivity type.

9. The semiconductor device according to claim 1, wherein
the first semiconductor layer contains the point defects and contains protons as an impurity of the first conductivity type, and
the second semiconductor layer does not contain the point defects and contains phosphorus or arsenic as an impurity of the first conductivity type.

10. The semiconductor device according to claim 1, wherein
the semiconductor substrate further includes an anode layer of a second conductivity type which is provided between the first electrode and the drift layer,
the first semiconductor layer does not contain the point defects, and
the second semiconductor layer is connected to the second electrode and contains the point defects.

11. The semiconductor device according to claim 10, wherein
the semiconductor substrate further includes a third semiconductor layer and a fourth semiconductor layer each having a peak impurity concentration of the second conductivity type which are adjacent to the first semiconductor layer and the second semiconductor layer and are provided between the drift layer and the second electrode, and
the fourth semiconductor layer is provided on the second electrode side of the third semiconductor layer.

12. The semiconductor device according to claim 10, wherein
the semiconductor substrate further includes a third semiconductor layer having a peak impurity concentration of the second conductivity type which is adjacent to the first semiconductor layer and the second semiconductor layer and is provided between the drift layer and the second electrode.

13. The semiconductor device according to claim 1, wherein
the semiconductor substrate further includes:
a base layer of a second conductivity type which is provided between the first electrode and the drift layer,
an emitter layer of the first conductivity type which is provided between the first electrode and the base layer, and
a third semiconductor layer of the second conductivity type which is provided on the second electrode side of the second semiconductor layer and is connected to the second electrode, and
the semiconductor device further comprises a gate electrode that is provided in a trench penetrating the emitter layer and the base layer via a gate insulating film.

14. The semiconductor device according to claim 1, further comprising:
a diode and an IGBT that are provided in the semiconductor substrate,
wherein in the diode, the semiconductor substrate includes
an anode layer of a second conductivity type which is provided between the first electrode and the drift layer,
the first semiconductor layer which does not contain the point defects, and
the second semiconductor layer which contains the point defects, and
in the IGBT, the semiconductor substrate includes
a base layer of the second conductivity type which is provided between the first electrode and the drift layer,
an emitter layer of the first conductivity type which is provided between the first electrode and the base layer,
the first semiconductor layer which contains the point defects, and
the second semiconductor layer which does not contain the point defects, and
the semiconductor device further comprises a gate electrode that is provided in a trench penetrating the emitter layer and the base layer via a gate insulating film.

15. The semiconductor device according to claim 14, wherein
the semiconductor substrate further includes a third semiconductor layer and a fourth semiconductor layer each having a peak impurity concentration of the second conductivity type which are adjacent to the first semiconductor layer and the second semiconductor layer and are provided between the drift layer and the second electrode,
the fourth semiconductor layer is provided on the second electrode side of the third semiconductor layer, and
the diode further includes the third semiconductor layer and the fourth semiconductor layer.

16. The semiconductor device according to claim 14, wherein
the semiconductor substrate further includes a third semiconductor layer having a peak impurity concentration of the second conductivity type which is adjacent to the first semiconductor layer and the second semiconductor layer and is provided between the drift layer and the second electrode, and
the diode further includes the third semiconductor layer.

17. The semiconductor device according to claim 13, wherein
the semiconductor device is an IGBT, and
the IGBT includes a dummy trench structure having a dummy electrode electrically connected to the first electrode.

18. The semiconductor device according to claim 14, wherein
the IGBT includes a dummy trench structure having a dummy electrode electrically connected to the first electrode.

19. The semiconductor device according to claim 15, wherein
the IGBT includes a dummy trench structure having a dummy electrode electrically connected to the first electrode.

20. The semiconductor device according to claim 16, wherein
the IGBT includes a dummy trench structure having a dummy electrode electrically connected to the first electrode.

21. A method of manufacturing a semiconductor device, the method comprising:
a step of preparing a semiconductor substrate of a first conductivity type having a first main surface provided with a first electrode and a second main surface opposite to the first main surface;
a step of implanting first ions into a portion of the semiconductor substrate on a side closer to the second main surface than a drift layer;
a step of implanting second ions into the semiconductor substrate on a side closer to the second main surface than the portion into which the first ions have been implanted;
a step of forming a first semiconductor layer of the first conductivity type by annealing the first ions;
a step of forming a second semiconductor layer of the first conductivity type by annealing the second ions; and
a step of forming a second electrode on the second main surface,
wherein one of the first semiconductor layer and the second semiconductor layer contains point defects while another of the first semiconductor layer and the second semiconductor layer does not contain the point defects, and
when a maximum oxygen concentration in the semiconductor substrate calculated using a conversion coefficient of ASTM F121-79 (Old ASTM) is defined as maximum [Oᵢ] and an impurity concentration of the first conductivity type in the drift layer is defined as C_{drift}, a relationship of
maximum [Oᵢ]=9.40×10¹⁶×ln(C_{drift})−2.27×10¹⁸
is satisfied.

22. The method according to claim 21, wherein
the step of implanting the second ions, the step of annealing the second ions, the step of implanting the first ions, and the step of annealing the first ions are performed in this order.

23. The method according to claim 21, further comprising:
a step of implanting third ions into a portion of the semiconductor substrate on a side closer to the second main surface than the drift layer;
a step of implanting fourth ions into another portion of the semiconductor substrate on a side closer to the second main surface than the portion into which the third ions have been implanted;
a step of forming a third semiconductor layer of a second conductivity type by annealing the third ions; and
a step of forming a fourth semiconductor layer of the second conductivity type by annealing the fourth ions,
wherein after performing a step of implanting fifth ions, a step of implanting sixth ions, the step of implanting the third ions, and the step of implanting the fourth ions, a step of annealing the fifth ions, a step of annealing the sixth ions, the step of annealing the third ions, and the step of annealing the fourth ions are performed in parallel.

24. The method according to claim 21, wherein
after performing a step of implanting fifth ions and a step of implanting sixth ions, a step of annealing the fifth ions and a step of annealing the sixth ions are performed in parallel.

25. The method according to claim 21, wherein
the first ions are implanted in an order of decreasing acceleration energy, and
a dose amount of the first ions implanted at a first acceleration energy is lower than a dose amount of the first ions implanted at a second acceleration energy lower than the first acceleration energy.

26. The method according to claim 21, wherein
the first ions contain protons, and
the second ions contain arsenic or phosphorus.

27. The method according to claim 21, wherein
the first ions are annealed at a temperature in a range of 375° C. to 425° C., inclusive, for a duration of 90 minutes or longer.

28. The method according to claim 21, wherein
the semiconductor substrate includes a semiconductor wafer produced by a MCZ method.

29. The method according to claim 21, wherein
the semiconductor substrate contains antimony as an impurity of the first conductivity type.
